(19) United States
(12) Patent Application Publication
(10) Pub. No.: US 2025/0112143 A1
(43) Pub. Date: Apr. 3, 2025

(54) SEMICONDUCTOR DEVICE, SEMICONDUCTOR MODULE AND MANUFACTURING METHOD

(71) Applicant: FUJI ELECTRIC CO., LTD., Kanagawa (JP)

(72) Inventors: Kohei YAMAUCHI, Hachioji-City (JP); Eiji MOCHIZUKI, Matsumoto-city (JP); Tatsuo NISHIZAWA, Matsumoto-city (JP); Hideki IWATA, Hino-City (JP); Yoshitaka NISHIMURA, Azumino-city (JP); Masakazu GEKINOZU, Hachioji-City (JP); Ryoga KIGUCHI, Hino-city (JP)

(21) Appl. No.: 18/957,825

(22) Filed: Nov. 24, 2024

Related U.S. Application Data
(63) Continuation of application No. PCT/JP2023/047275, filed on Dec. 28, 2023.

(30) Foreign Application Priority Data
Dec. 28, 2022 (JP) 2022-211688
Jun. 22, 2023 (JP) 2023-102768

(51) Int. Cl. H01L 23/498; H01L 23/31; H01L 23/40

(52) U.S. Cl. CPC H01L 23/49844; H01L 23/3178; H01L 23/4006; H01L 23/49811; H10D 62/8325; H01L 2023/4062

(57) ABSTRACT

Provided is a semiconductor device having a switching element in which a first main electrode plate, a second main electrode plate and a control electrode plate are provided on one surface, a first main electrode being connected to the first main electrode plate, a second main electrode being connected to the second main electrode plate, and a control electrode being connected to the control electrode plate, and a semiconductor module including the semiconductor device.

The contents of the following patent application(s) are incorporated herein by reference:

NO. 2022-211688 filed in JP on Dec. 28, 2022

NO. 2023-102768 filed in JP on Jun. 22, 2023

NO. PCT/JP2023/047275 filed in WO on Dec. 28, 2023.

### BACKGROUND

### 1. Technical Field

The present invention relates to a semiconductor device, a semiconductor module and a manufacturing method.

### 2. Related Art

Patent Document 1 describes that “A semiconductor module 100 including a semiconductor assembly 110 including a plurality of semiconductor chips 30 can constitute a power device such as an inverter as a whole and an IPM (Intelligent Power Module) including a control circuit” (Paragraph 0031), “As an example, a PCB 40 is electrically connected to a semiconductor chip 30 by a bonding wire 55” (Paragraph 0032), “Nickel plating may be applied to an external connection part 50. A large current can be applied to each main terminal 52 of the semiconductor assembly 110 because a copper bus bar is connected to the external connection part 50” (Paragraph 0033), and “The semiconductor assembly 110 may have a metal wiring plate 70 for electrically connecting the semiconductor chip 30 and the main terminal 52. Instead of the metal wiring plate 70, the semiconductor chip 30 and the main terminal 52 may be electrically connected to each other by a conductive member such as a wire or ribbon” (Paragraph 0035).

Patent Document 2 describes that “Two semiconductor elements 3 are electrically connected by a wiring member W1. One of the semiconductor elements 3 is electrically connected to a second circuit layer 24 via a wiring member W2. The second circuit layer 24 is electrically connected to an external terminal 27, which will be described below, via a wiring member W3. Another of the semiconductor elements 3 is electrically connected to a third circuit layer 25 via a wiring member W4. The third circuit layer 25 is electrically connected to another external terminal 27 via a wiring member W5.” (Paragraph 0023), “A conductive wire may be used as each wiring member described above. Any one of gold, copper, aluminum, gold alloy, copper alloy, or aluminum alloy, or a combination thereof can be used as a material of the electrically conductive wire. A member other than electrically conductive wire can also be used as the wiring member. For example, a ribbon can be used as the wiring member.” (Paragraph 0024), and “The insulating circuit board 2 and the semiconductor element 3 are covered by a case 11 as a surrounding housing. The case 11 is constructed with an annular wall 12 surrounding an outer circumference side of the insulating circuit board 2 and a lid 13 covering the insulating circuit board 2 and the semiconductor elements 3 from above, and is formed of, for example, synthetic resin.” (Paragraph 0025).

### PRIOR ART DOCUMENTS

### Patent Documents

Patent Document 1: Japanese Patent Application Publication No. 2021-2610

Patent Document 2: International Publication No. 2020/121680

### BRIEF DESCRIPTION OF THE DRAWINGS

FIG. 1 is a perspective view of a switching element 10 according to the present embodiment.

FIG. 2 is a perspective view of a semiconductor device 200 according to the present embodiment.

FIG. 3 illustrates a manufacturing method of the semiconductor device 200 according to the present embodiment.

FIG. 4 is a perspective view of a configuration in which a second main electrode plate 230 is bonded to the switching element 10 according to the present embodiment.

FIG. 5 is a perspective view of a mounting substrate 210 according to the present embodiment.

FIG. 6 is a perspective view of a configuration in which a switching element 10 to which the second main electrode plate 230 is bonded is bonded to the mounting substrate 210 according to the present embodiment.

FIG. 7 is a perspective view of a configuration in which a first main electrode plate 220, a control electrode plate 240, and a sub-electrode plate 250 are bonded to the mounting substrate 210 according to the present embodiment.

FIG. 8 is a perspective view of a semiconductor module 800 according to the present embodiment.

FIG. 9 is a schematic view illustrating an internal structure of the semiconductor module 800 according to the present embodiment.

FIG. 10 illustrates a connection of each wiring within the semiconductor module 800 according to the present embodiment.

FIG. 11 illustrates a manufacturing method of the semiconductor module 800 according to the present embodiment.

FIG. 12 is a schematic view of a manufacturing method of the semiconductor module 800 according to the present embodiment.

FIG. 13 is a schematic view of a cross-section of the semiconductor module 800 according to the present embodiment.

FIG. 14 is a schematic view in which a region S in FIG. 13 is enlarged.

FIG. 15 is a perspective view of a semiconductor device 1500 according to a first variant of the present embodiment.

FIG. 16 is a perspective view of a semiconductor module 1600 according to a second variant of the present embodiment.

FIG. 17 is a view of the semiconductor device 1600 according to the second variant of the present embodiment when viewed from a side with a heat radiator 1630.

FIG. 18 illustrates a connection of each wiring within a semiconductor module 1800 according to a third variant of the present embodiment.

FIG. 19 illustrates a connection of each wiring within a semiconductor module 1900 according to a fourth variant of the present embodiment.

FIG. 20 illustrates a semiconductor module 2000 according to a fifth variant of the present embodiment.

FIG. 21 illustrates a semiconductor module 2100 according to a sixth variant of the present embodiment.

FIG. 22 illustrates a semiconductor module 2200 according to a seventh variant of the present embodiment.

FIG. 23 is a schematic view of a cross-section of a semiconductor module 2300 according to an eighth variant of the present embodiment.

FIG. 24 is a schematic view of a cross-section of a semiconductor module 2400 according to a ninth variant of the present embodiment.

FIG. 25 is a schematic view of a cross-section of a semiconductor module 2500 according to a tenth variant of the present embodiment.

FIG. 26 is a schematic view of a cross-section of a semiconductor module 2600 according to an eleventh variant of the present embodiment.

FIG. 27 is a schematic view of a cross-section of a semiconductor module 2700 according to a twelfth variant of the present embodiment.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention.

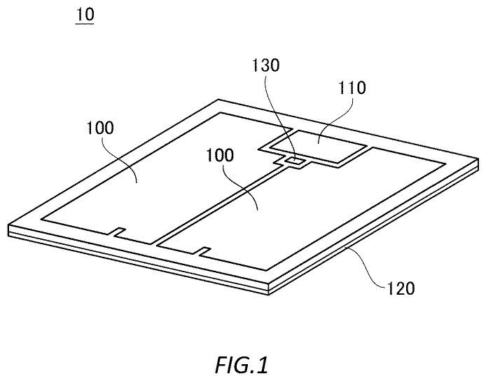

FIG. 1 is a perspective view of a switching element 10 according to the present embodiment. The switching element 10 is a semiconductor switching element such as a MOSFET or Metal-Oxide-Semiconductor Field-Effect Transistor. The switching element 10 may be a power MOSFET having a vertical structure. The switching element 10 may be a Si semiconductor element such as a Si-MOSFET, may be a SiC semiconductor element such as a SiC-MOSFET which enables a faster switching, or may be a semiconductor element using a wide-bandgap semiconductor such as GaN, diamond, gallium nitride-based material, gallium oxide-based material, AlN, AlGaN, or ZnO. Instead of the above, the switching element 10 may be a semiconductor switching element such as an IGBT or Insulated Gate Bipolar Transistor or may be a SiC-IGBT. The switching element 10 may be a HEMT or High Electron Mobility Transistor.

The switching element 10 may be a semiconductor chip having a first main electrode 100 and a control electrode 110 on one surface, which is a surface on an upper side in the figure, and having a second main electrode 120 on an opposite surface. In the example of this figure, the switching element 10 further has a sense electrode 130 on the surface on the upper side in the figure. When the switching element 10 is a MOSFET, the switching element 10 has a source and a drain as the first main electrode 100 and the second main electrode 120, has a gate as the control electrode 110, and has a sense source as the sense electrode 130. When the switching element 10 is an IGBT, the switching element 10 has an emitter and a collector as the first main electrode 100 and the second main electrode 120, has a gate as the control electrode 110, and has a sense emitter as the sense electrode 130. In this embodiment, for convenience of description, the switching element 10 is illustrated as a MOSFET.

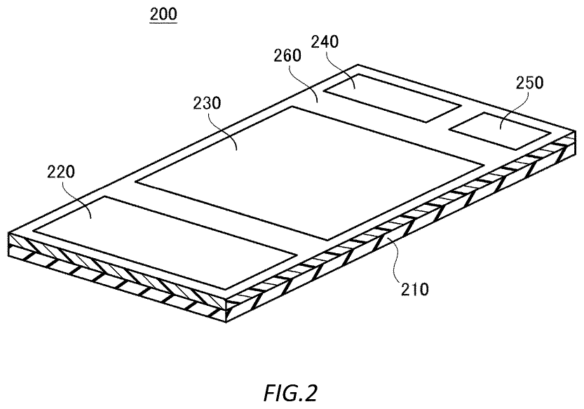

FIG. 2 is a perspective view of a semiconductor device 200 according to the present embodiment. In general, a semiconductor module using a switching element such as the switching element 10 illustrated in FIG. 1 has a structure in which one surface of the switching element, which is, for example, a surface on a side with the second main electrode 120, is bonded to a wiring pattern on a substrate and each electrode on another surface, which is, for example, each of the first main electrode 100, the control electrode 110, and the sense electrode 130, is electrically connected to another wiring pattern by wire bonding. Such a semiconductor module is implemented as an integral module by encapsulating, using a resin, a substrate on which the switching element is mounted, each bonding wire, and each metal plate connected to a positive terminal, a negative terminal and an output terminal.

In contrast, the semiconductor device 200 has a structure in which each electrode plate electrically connected to each electrode of the switching element 10 is exposed to one surface of the plate-shaped semiconductor device 200. In this embodiment, the semiconductor device 200 includes a mounting substrate 210, a first main electrode plate 220, a second main electrode plate 230, a control electrode plate 240, a sub-electrode plate 250, and an encapsulating portion 260.

The switching element 10 is mounted on a mounting surface, which is a surface on an upper side in the figure, of the mounting substrate 210. The first main electrode plate 220 is electrically connected to the first main electrode 100 of the switching element 10. The second main electrode plate 230 is electrically connected to the second main electrode 120 of the switching element 10. The control electrode plate 240 is electrically connected to the control electrode 110 of the switching element 10. The sub-electrode plate 250 is electrically connected to the first main electrode 100 of the switching element 10. Here, the first main electrode plate 220, the second main electrode plate 230, the control electrode plate 240, and the sub-electrode plate 250 are exposed to a surface opposite to a side with the mounting substrate 210 of the semiconductor device 200, the surface being on a side with the mounting surface for the switching element 10 in the mounting substrate 210. The encapsulating portion 260 covers the mounting surface for the switching element 10 in the mounting substrate 210 while exposing the first main electrode plate 220, the second main electrode plate 230, the control electrode plate 240, and the sub-electrode plate 250.

Instead of modularizing the switching element such as the switching element 10 as previously described, by bonding each electrode plate on one surface of the semiconductor device 200 to a wiring pattern on the substrate using the semiconductor device 200 of the present embodiment, all the electrodes necessary for the switching element 10 can be electrically connected to respective wirings on the substrate without wire bonding.

The semiconductor device 200 may further have an electrode plate to be electrically connected to the sense electrode 130 on a same surface as, for example, the first main electrode plate 220. While both of the first main electrode plate 220 and the sub-electrode plate 250 are electrically connected to the first main electrode 100 of the switching element 10, the first main electrode plate 220 has a larger area and is used for a large current to flow therethrough and the sub-electrode plate 250 is used for controlling the switching element 10 in a pair with the control electrode plate 240. In another form, the semiconductor device 200 may not include the sub-electrode plate 250. In this case, the first main electrode plate 220 is also used for controlling the switching element 10.

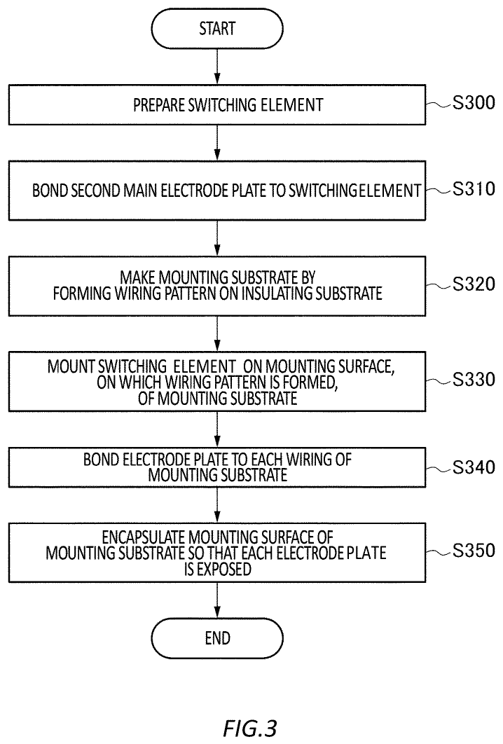

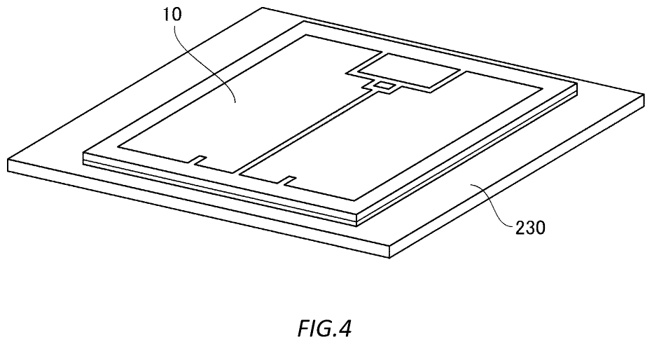

FIG. 3 illustrates a manufacturing method of the semiconductor device 200 according to the present embodiment. Hereinafter, the manufacturing method of the semiconductor device 200 will be described with reference to FIGS. 4 to 7 illustrating a configuration in a middle of manufacture of the semiconductor device 200. In S300 or step 300, the switching element 10 is prepared, which has the first main electrode 100 and the control electrode 110 on one surface and has the second main electrode 120 on an opposite surface.

In S310, the second main electrode plate 230 is bonded to a surface on a side with the second main electrode 120 of the switching element 10. FIG. 4 is a perspective view of a configuration in which a second main electrode plate 230 is bonded to the switching element 10 according to the present embodiment. The second main electrode plate 230 is a conductive plate such as a copper plate. The second main electrode plate 230 may be bonded by using a nano-silver sintering agent or may be bonded by gold-to-gold direct bonding to the second main electrode 120. Thus, the second main electrode plate 230 is electrically connected to the second main electrode 120 of the switching element 10. As an alternative to the above, the second main electrode plate 230 may be bonded by a solder material or copper-to-copper direct bonding. A second main electrode of the switching element 10 may be bonded to a plurality of bumps arrayed regularly or irregularly on the second main electrode plate 230.

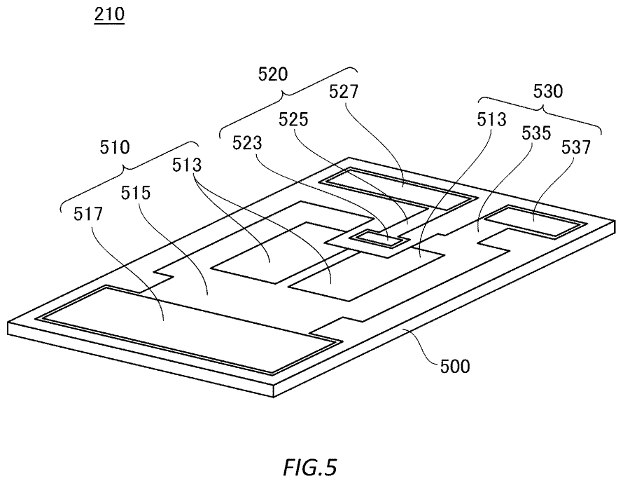

In S320, the mounting substrate 210 is made. FIG. 5 is a perspective view of the mounting substrate 210 according to the present embodiment. In this process, the mounting substrate 210 is made, which has a wiring pattern of first main electrode wiring 510, control wiring 520, and sub-wiring 530 on a mounting surface, to which the switching element 10 is intended to be mounted, in an insulating substrate 500 made of a material such as Si, silicon nitride, or aluminum nitride. For example, in addition to the above, the insulating substrate 500 may be made by using a ceramic material.

The first main electrode wiring 510 is formed from a conductive metal film or metal plate made of, for example, copper. The first main electrode wiring 510 includes a first main electrode contact 513, wiring 515, and a first main electrode plate contact 517. The first main electrode contact 513 is an area to which the first main electrode 100 of the switching element 10 is connected. The wiring 515 electrically connects the first main electrode contact 513 and the first main electrode plate contact 517. The first main electrode plate contact 517 is an area to which the first main electrode plate 220 is connected.

Similarly to the first main electrode wiring 510, the control wiring 520 is formed from a conductive metal film or metal plate made of, for example, copper. The control wiring 520 includes a control electrode contact 523, wiring 525, and a control electrode plate contact 527. The control electrode contact 523 is an area to which the control electrode 110 of the switching element 10 is connected. The wiring 525 electrically connects the control electrode contact 523 and the control electrode plate contact 527. The control electrode plate contact 527 is an area to which the control electrode plate 240 is connected.

Similarly to the first main electrode wiring 510, the sub-wiring 530 is formed from a conductive metal film or metal plate made of, for example, copper. The sub-wiring 530 includes a first main electrode contact 513, wiring 535, and a sub-electrode plate contact 537. The first main electrode contact 513 is shared with the first main electrode wiring 510. The sub-wiring 530 may utilize a part of the first main electrode contact 513 used by the first main electrode wiring 510. The wiring 535 electrically connects the first main electrode contact 513 and the sub-electrode plate contact 537. A wiring width of the wiring 535 may be smaller than that of the wiring 515. The sub-electrode plate contact 537 is an area to which the sub-electrode plate 250 is connected.

Here, an area bonded to each electrode of the switching element 10 such as the first main electrode contact 513 and the first main electrode plate contact 517 of the first main electrode wiring 510, the control electrode contact 523 and the control electrode plate contact 527 of the control wiring 520, and the sub-electrode plate contact 537 of the sub-wiring 530, or each electrode plate such as the first main electrode plate 220, the second main electrode plate 230, the control electrode plate 240 and the sub-electrode plate 250 may each have a plurality of bumps arrayed regularly or irregularly. The plurality of bumps may each be a conductive metal bump made of, for example, gold. The plurality of bumps may formed by, for example, arranging a conductive metal bump precursor in each area by transfer and sintering the bump precursor to be cured.

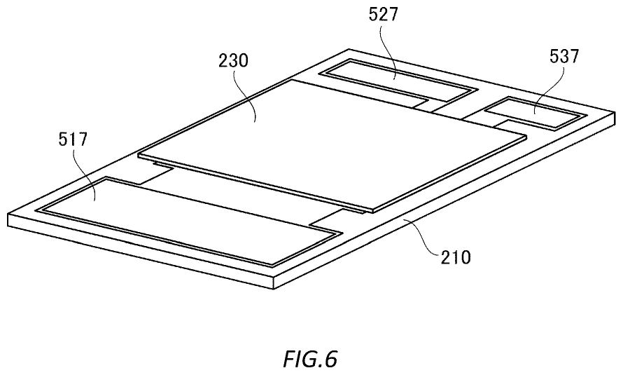

In S330, the switching element 10 is mounted on the mounting surface for the mounting substrate 210 on which each wiring pattern is formed. FIG. 6 is a perspective view of a configuration in which a switching element 10 to which the second main electrode plate 230 is bonded is bonded to the mounting substrate 210 according to the present embodiment. The switching element 10 to which the second main electrode plate 230 is bonded as illustrated in FIG. 4 is bonded to the mounting surface for the mounting substrate 210 so that a surface on an upper side of the switching element 10 in FIG. 4 is oriented downward. Thus, the first main electrode 100 of the switching element 10 is bonded to the first main electrode contact 513 of the first main electrode wiring 510 and the sub-wiring 530, and the control electrode 110 of the switching element 10 is bonded to the control electrode contact 523 of the control wiring 520. This bonding method may be similar to the bonding method used to bond the second main electrode plate 230 to the second main electrode 120.

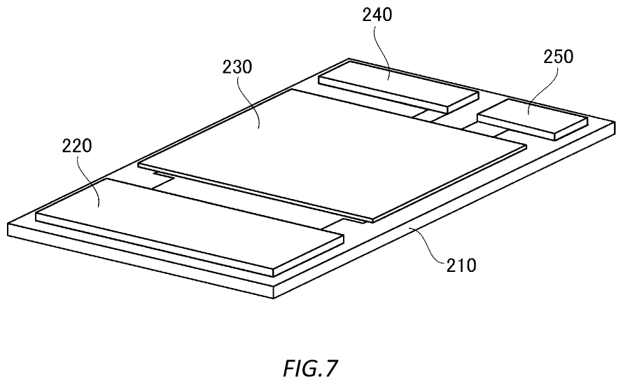

In S340, each electrode plate is bonded to each wiring of the mounting substrate 210. FIG. 7 is a perspective view of a configuration in which the first main electrode plate 220, the control electrode plate 240, and the sub-electrode plate 250 are bonded to the mounting substrate 210 according to the present embodiment. As illustrated in FIG. 6, the first main electrode plate contact 517 of the first main electrode wiring 510, the control electrode plate contact 527 of the control wiring 520, and the sub-electrode plate contact 537 of the sub-wiring 530 are positioned in an area, where the switching element 10 is not arranged, on the mounting surface of the mounting substrate 210 onto which the switching element 10 is intended to be mounted. In this process, the first main electrode plate 220, the control electrode plate 240, and the sub-electrode plate 250 are respectively bonded to the first main electrode plate contact 517, the control electrode plate contact 527, and the sub-electrode plate contact 537 as such. This bonding method may be similar to the bonding method used to bond the second main electrode plate 230 to the second main electrode 120.

Thus, the first main electrode plate 220, the control electrode plate 240, and the sub-electrode plate 250 are positioned in an area, where the switching element 10 is not arranged, on the mounting surface for the switching element 10, and are respectively electrically connected to the first main electrode wiring 510, the control wiring 520, and the sub-wiring 530. In this manner, the mounting substrate 210 is made, which has the insulating substrate 500 and the first main electrode wiring 510, the first main electrode plate 220, the control wiring 520, the control electrode plate 240, the sub-wiring 530 and the sub-electrode plate 250 that are formed on the insulating substrate 500.

Here, in the semiconductor device 200 according to the present embodiment, on the mounting surface for the switching element 10 in the mounting substrate 210, the switching element 10 is arranged between the first main electrode plate 220 and the control electrode plate 240. The sub-electrode plate 250 may be arranged on a same side as the control electrode plate 240 relative to the switching element 10. Thus, in the semiconductor device 200, control wiring can be connected to the control electrode plate 240 and the sub-electrode plate 250 positioned at one end of the semiconductor device 200.

In S350, the semiconductor device 200 illustrated in FIG. 2 is obtained by forming the encapsulating portion 260 by encapsulating the mounting surface for the mounting substrate 210 using the encapsulating material so that each electrode plate is exposed. Here, the encapsulating portion 260 covers the mounting surface for the switching element 10 in the mounting substrate 210 and a surface on a side with the mounting substrate 210 in the switching element 10 while exposing the first main electrode plate 220, the second main electrode plate 230, the control electrode plate 240, and the sub-electrode plate 250 to a terminal surface, which is a surface on an upper side in FIG. 2, of the semiconductor device 200. This encapsulation may be resin encapsulation using a molding material.

In this process, after encapsulating to cover the mounting surface for the switching element 10 in the mounting substrate 210 and the surface on the side with the mounting substrate 210 in the switching element 10, the terminal surface of the semiconductor device 200 may be ground to remove an excess amount of the encapsulating material so as to expose each electrode plate. In another embodiment, the encapsulation process may be omitted, and the semiconductor device 200 may not include the encapsulating portion 260. After this process, an anti-oxidation film may be formed, for example, by plating an exposed surface of each electrode plate with Sn.

According to the manufacturing method presented above, the semiconductor device 200 can be manufactured in which each terminal electrically connected to each electrode of the switching element 10 is exposed to one surface. Although the second main electrode plate 230 is bonded to a surface on a side with the second main electrode 120 of the switching element 10 in S310 in the manufacturing method presented above, this process may be omitted. In this case, the second main electrode 120 may be directly exposed to the terminal surface of the semiconductor device 200.

In the manufacturing method presented above, the order of each process may be changed if possible. For example, S340 may be performed before S330, so that the switching element 10 may be mounted on the mounting substrate 210 after each electrode plate is bonded to each wiring of the mounting substrate 210. S310 may be performed after S330, so that the second main electrode plate 230 is bonded to a surface on a side with the second main electrode 120 of the switching element 10 after the mounting substrate 210 is mounted on the switching element 10. Any of S300 or S310, or S320 may be performed prior to others, or S300 and S310, and S320 may be performed in parallel.

The semiconductor device 200 may include a temperature sensing diode or another temperature sensor for measuring a temperature of the semiconductor device 200 or the switching element 10. In this case, the semiconductor device 200 may further have, for example, an electrode plate connected to an electrode of a temperature sensor such as an anode electrode and a cathode electrode of the temperature sensing diode on the same surface as, for example, the first main electrode plate 220.

A number of electrode plates arranged on the same surface as, for example, the first main electrode plate 220, and, for example, a size, a shape and a kind of each electrode plate in the semiconductor device 200 may be selected as needed according to a usage form of the semiconductor device 200, the temperature sensor added to the semiconductor device 200, or, for example, another additional circuit. For example, an area for the control electrode plate 240 of the semiconductor device 200 may be further reduced, and a new electrode plate may be provided in an area emptied thereby. The electrode plate newly provided includes at least one of, for example, a sense electrode plate electrically connected to the sense electrode 130, one or two or more temperature sense electrode plates each connected to an electrode of the temperature sensor of, for example, the switching element 10 as described above, or, for example, an electrode plate having a same electrical potential as the second main electrode plate 230, which is, for example, a sub-electrode plate. For example, another electrode plate such as the second main electrode plate 230 may be extended into the area emptied by reducing the area for the control electrode plate 240.

Such an additional electrode may be used for, for example, electrical measurement for monitoring a state of the semiconductor device 200 or the switching element 10. Such an additional electrode may be arranged at a position away from the first main electrode plate 220 and the second main electrode plate 230, and a flow path of a large current such as main wiring connected to these main electrode plates, for example, in a vicinity of an edge on a side where the control electrode plate 240 and the sub-electrode plate 250 are provided in the semiconductor device 200. Thus, the semiconductor device 200 can reduce an influence that at least one of a noise or heat generated due to a flowing large current has on the additional electrode.

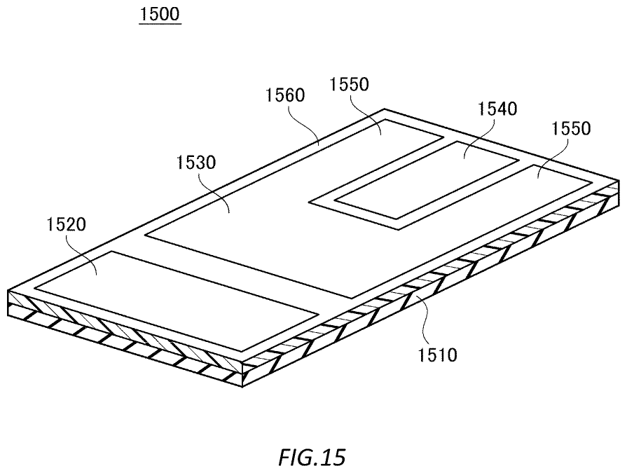

Another second sub-electrode plate other than the sub-electrode plate 250 may be provided, for example, in the area emptied by reducing the area for the control electrode plate 240. The sub-electrode plate 250, which is also illustrated as a “first sub-electrode plate”, and the second sub-electrode plate may be arranged on opposing sides of the control electrode plate 240 so that the control electrode plate 240 is sandwiched between the sub-electrode plates. Such an arrangement of sandwiching the control electrode plate between the two sub-electrode plates are similar to that of the control electrode plate 1540 and the two sub-electrode plates 1550 in FIG. 15. To realize such an arrangement, in addition to the sub-wiring 530, the mounting substrate 210 may have, on the mounting surface for the switching element 10, second sub-wiring electrically connecting the first main electrode 100 of the switching element 10 and the second sub-electrode plate. The sub-wiring 530, which is also illustrated as a “first sub-wiring” and the second sub-wiring may be arranged on opposing sides of the control wiring 520 so that the control wiring 520 is sandwiched between the two. In this manner, by sandwiching the control electrode plate 240 between the two sub-electrode plates, the semiconductor device 200 can reduce wiring inductance in a flow path of the current for driving the semiconductor device 200, that is, a current for a control signal flowing to the control electrode 110 of the switching element 10.

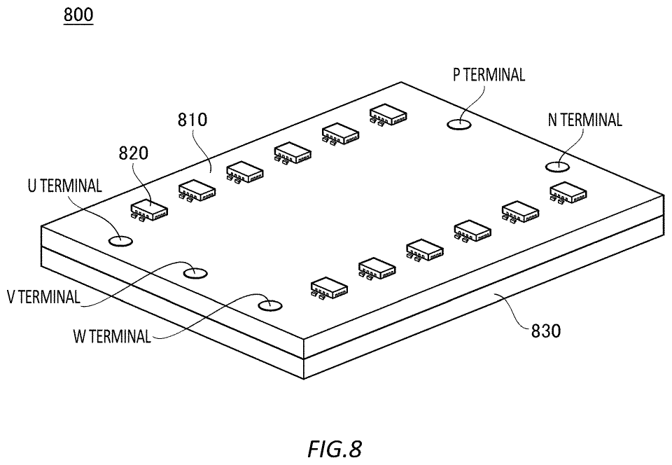

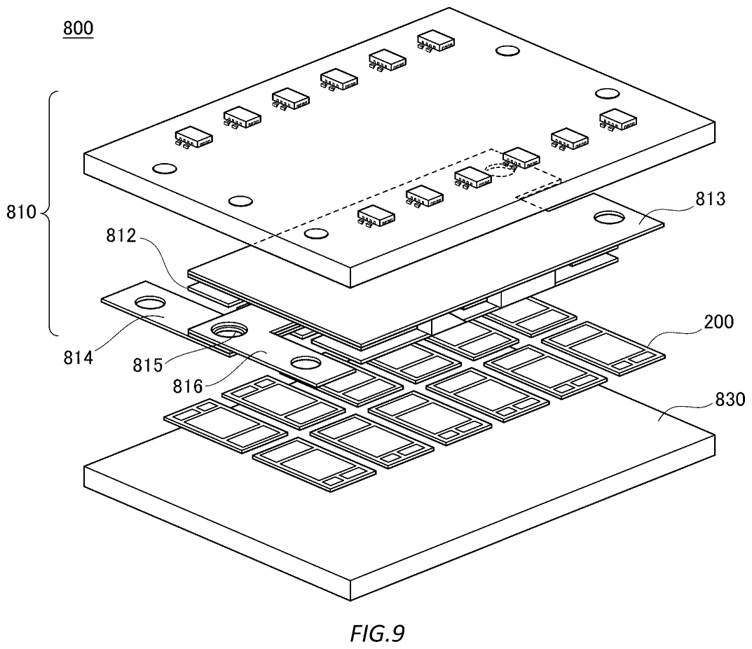

FIG. 8 is a perspective view of the semiconductor module 800 according to the present embodiment. FIG. 9 is a schematic view illustrating an internal structure of the semiconductor module 800 according to the present embodiment. The semiconductor module 800 includes one or more semiconductor devices 200, a main substrate 810, one or more control devices 820, and a heat radiator 830.

The semiconductor module 800 according to the present embodiment is an inverter device and includes a plurality of semiconductor devices 200. The plurality of semiconductor devices 200 may be respectively allocated to an upper arm and a lower arm for each phase among one or more phases. In the examples of FIGS. 8 and 9, the semiconductor module 800 is a three-phase inverter. For each phase, two semiconductor devices 200 are allocated to an upper arm and two semiconductor devices 200 are allocated to a lower arm. Therefore, the semiconductor module 800 includes twelve, which is calculated by three phases * (two for the upper arm and two for the lower arm), semiconductor devices 200. The semiconductor module 800 may include any number of semiconductor devices 200 according to applications.

The main substrate 810 may be a printed wiring substrate. Each of the first main electrode plate 220, the second main electrode plate 230, the control electrode plate 240, and the sub-electrode plate 250 of each of the plurality of semiconductor devices 200 is connected to each electrode on a back surface of the main substrate 810. An inner layer of the main substrate 810 has P wiring 812, N wiring 813, U wiring 814, V wiring 815, and W wiring 816. In FIG. 9, in order to clearly show a structure of a wiring layer, the P wiring 812, the N wiring 813, the U wiring 814, the V wiring 815, and the W wiring 816 are separately schematically illustrated below the substrate of the main substrate 810.

The P wiring 812, the N wiring 813, the U wiring 814, the V wiring 815, and the W wiring 816 may each be a conductive pattern formed in a layer different from each other in the inner layer of the main substrate 810. In this embodiment, the N wiring 813 is formed as two or more layers connected by, for example, a conductive through via, and at least a part of each of the P wiring 812, the U wiring 814, the V wiring 815, and the W wiring 816 is sandwiched between the two layers of the N wiring 813.

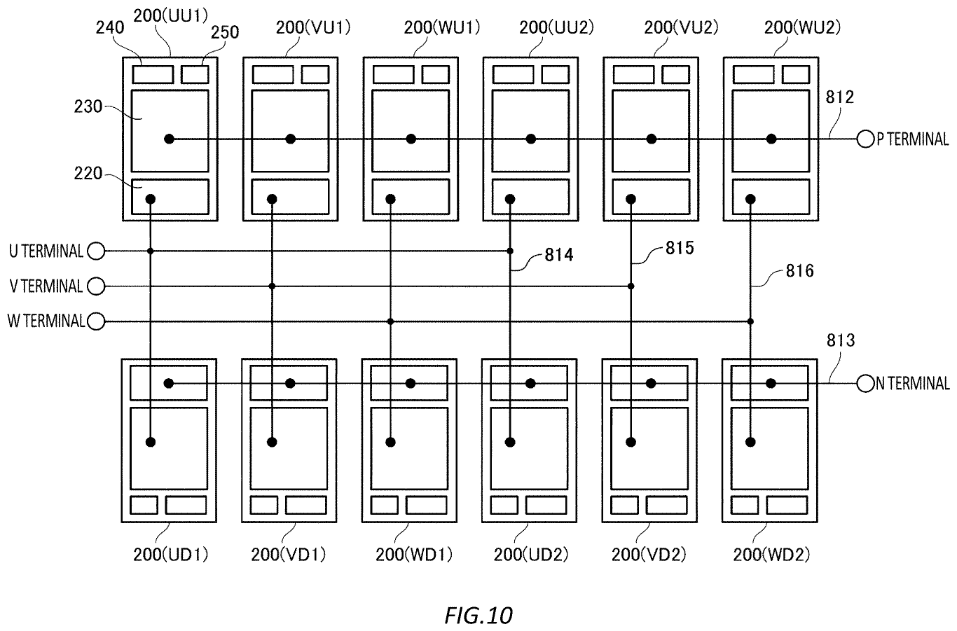

The main substrate 810 has, on its front surface, a terminal connected to the first main electrode plate 220 of the plurality of semiconductor devices 200 via wiring within the main substrate 810 and a terminal connected to the second main electrode plate 230 via wiring within the main substrate 810. In the example of the present embodiment, the main substrate 810 has, on its front surface, a P terminal, which is a positive terminal, an N terminal, which is a negative terminal, a U terminal, which is a U-phase output terminal, a V terminal, which is a V-phase output terminal, and a W terminal, which is a W-phase output terminal. The connection between each terminal provided on the front surface of the main substrate 810 and the one or more semiconductor devices 200 by each wiring such as the P wiring 812 will be described below by using FIG. 10.

The plurality of control devices 820 are mounted on the front surface of the main substrate 810. Each of the one or more control devices 820 is electrically connected to the control electrode plate 240 and the sub-electrode plate 250 of each of the one or more semiconductor devices 200 via the wiring within the main substrate 810. Each control device 820 controls the semiconductor device 200 by controlling a voltage of the control electrode plate 240 relative to the sub-electrode plate 250 of the semiconductor device 200. Each control device 820 may control one semiconductor device 200 by being connected to the one semiconductor device 200 or may control two or more semiconductor devices 200 by being connected to the two or more semiconductor devices 200. The one or more control devices 820 may control the one or more semiconductor devices 200 by receiving a control signal from an external control apparatus.

The heat radiator 830 may be in contact with a surface, on a side opposite to the main substrate 810, of the one or more semiconductor devices 200. The heat radiator 830 may be a heat spreader, a heat sink, or a liquid-cooling heat exchanger.

FIG. 10 illustrates a connection of each wiring within the semiconductor module 800 according to the present embodiment. In this figure, the semiconductor device 200 (UU1) and the semiconductor device 200 (UU2) are allocated to a U-phase upper arm, and the semiconductor device 200 (UD1) and the semiconductor device 200 (UD2) are allocated to a U-phase lower arm. The second main electrode plate 230 of each semiconductor device 200 for the U-phase upper arm is connected to a P terminal via the P wiring 812. The first main electrode plate 220 of each semiconductor device 200 for the U-phase upper arm is connected to the U terminal via the U wiring 814. The second main electrode plate 230 of each semiconductor device 200 for the U-phase lower arm is connected to the U terminal and the first main electrode plate 220 of each semiconductor device 200 for the U-phase upper arm via the U wiring 814. The first main electrode plate 220 of each semiconductor device 200 for the U-phase lower arm is connected to the N terminal via the N wiring 813. By this connection, each semiconductor device 200 for the U-phase upper arm and each semiconductor device 200 for the U-phase lower arm are connected in series in this order between the P terminal and the N terminal, and a node between the first main electrode plate 220, which is for example a source, of each semiconductor device 200 for the U-phase upper arm and the second main electrode plate 230, which is for example a drain, of each semiconductor device 200 for the U-phase lower arm are connected to the U terminal.

The semiconductor device 200 (VU1) and the semiconductor device 200 (VU2) are allocated to a V-phase upper arm and the semiconductor device 200 (VD1) and the semiconductor device 200 (VD2) are allocated to a V-phase lower arm. Each semiconductor device 200 for the V-phase upper arm and the V-phase lower arm is connected similarly to each semiconductor device 200 for the U-phase upper arm and the U-phase lower arm except that it is connected to the V terminal instead of the U terminal.

The semiconductor device 200 (WU1) and the semiconductor device 200 (WU2) are allocated to a W-phase upper arm and the semiconductor device 200 (WD1) and the semiconductor device 200 (WD2) are allocated to a W-phase lower arm. Each semiconductor device 200 for the W-phase upper arm and the W-phase lower arm is connected similarly to each semiconductor device 200 for the U-phase upper arm and the U-phase lower arm except that is connected to the W terminal instead of the U terminal.

As illustrated in this figure, on the back surface of the main substrate 810, each semiconductor device 200 allocated to the upper arm for each phase among the plurality of semiconductor devices 200 may be arranged in a line, which is a line on an upper side in the figure. On the back surface of the main substrate 810, each semiconductor device 200 allocated to the lower arm for each phase among the plurality of semiconductor devices 200 may be arranged in a line, which is a line on a lower side in the figure, side by side with the line of each semiconductor device 200 allocated to the upper arm for each phase. With such an arrangement, the second main electrode plate 230 of each semiconductor device 200 for the upper arms and the first main electrode plate 220 of each semiconductor device 200 for the lower arms are respectively arranged in lines, so that the P wiring 812 and the N wiring 813 can extend respectively in an array direction of each semiconductor device 200 for the upper arms and in an array direction of each semiconductor device 200 for the lower arms so as to be connected to each semiconductor device 200. Accordingly, the U wiring 814, the V wiring 815, and the W wiring 816 can also extend in the array direction of each semiconductor device 200 so as to be connected to the first main electrode plate 220 of each semiconductor device 200 for a corresponding upper arm and the second main electrode plate 230 of each semiconductor device 200 for a corresponding lower arm.

As illustrated in this figure, on the back surface of the main substrate 810, each semiconductor device 200 allocated to the upper arm for each phase may be arranged in an orientation in which the first main electrode plate 220 is positioned on a side with the semiconductor device 200 allocated to the opposing lower arm among the plurality of semiconductor devices 200, that is, an orientation in which the first main electrode plate 220 is located on a lower side in the figure. On the back surface of the main substrate 810, each semiconductor device 200 allocated to the lower arm for each phase may be arranged in an orientation in which the first main electrode plate 220 is positioned on a side with the semiconductor device 200 allocated to the opposing upper arm among the plurality of semiconductor devices 200, that is, an orientation in which the first main electrode plate 220 is located on an upper side in the figure. In such an arrangement, the control electrode plate 240 and the sub-electrode plate 250 of each semiconductor device 200 are positioned at an end, on a side opposite to the semiconductor device 200 for the opposing arms, of the semiconductor device 200. Thus, the semiconductor devices 200 for the upper and lower arms oppose each other, and control wiring can be arranged on an outside of an area in which the P wiring 812, the N wiring 813, the U wiring 814, the V wiring 815, and the W wiring 816, through which a large current flows, are arranged.

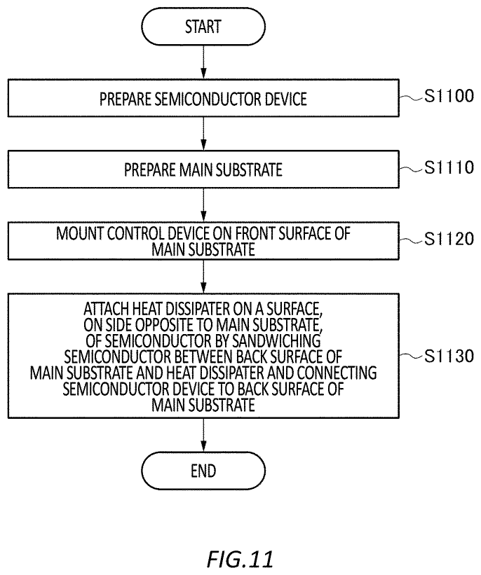

FIG. 11 illustrates a manufacturing method of the semiconductor module 800 according to the present embodiment. In S1100, at least one semiconductor device 200 is prepared. In S1110, a main substrate 810 is prepared. The first main electrode plate 220, the second main electrode plate 230, the control electrode plate 240, and the sub-electrode plate 250 of at least one semiconductor device 200 are to be connected to a back surface of the main substrate 810.

In S1120, the at least one control device 820 is mounted on a front surface of the main substrate 810 by, for example, soldering the at least one control device 820 to the front surface of the main substrate 810. In S1130, the at least one semiconductor device 200 is sandwiched between the back surface of the main substrate 810 and the heat radiator 830, each electrode plate of the semiconductor device 200 is connected to the back surface of the main substrate 810, and the heat radiator 830 is attached to an surface, on a side opposite to the main substrate 810, of each semiconductor device 200.

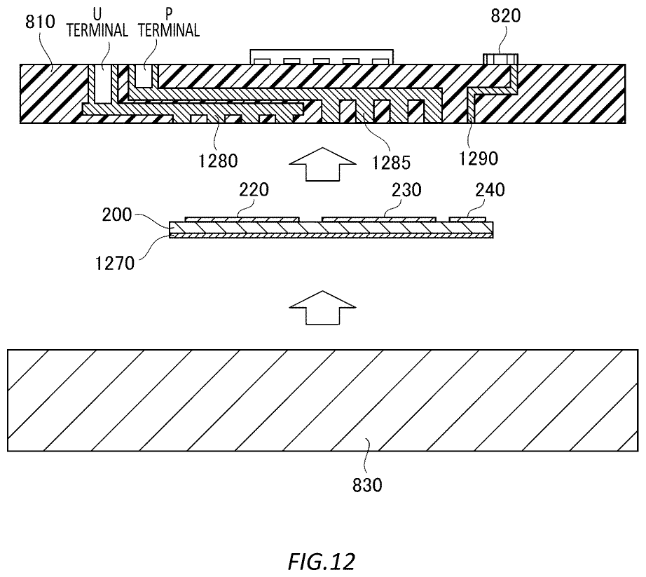

FIG. 12 is a schematic view of a manufacturing method of the semiconductor module 800 according to the present embodiment. In particular, this figure schematically illustrates a process of S1130 shown in FIG. 11 by using a schematic cross-sectional structure of the main substrate 810, the semiconductor device 200, and the heat radiator 830. The main substrate 810 has at least one control device 820 mounted on its front surface, and has each terminal such as the P terminal and the U terminal. Each terminal such as the P terminal and the U terminal may have a structure formed by, for example, plating a conductive metal layer on an inner surface of a non-through hole or a through hole having a depth reaching at least the wiring layer having a wiring pattern to which each terminal is electrically connected. Instead of the above, each terminal may be formed by embedding, in the main substrate 810, a conductive terminal member having a depth reaching at least the wiring layer having a wiring pattern to which each terminal is electrically connected, which is for example a column-shaped copper part having a screw hole on its inner side.

The main substrate 810 has, on its back surface, a first main electrode plate contact 1280 to be bonded to the first main electrode plate 220 of the semiconductor device 200, a second main electrode plate contact 1285 to be bonded to the second main electrode plate 230, and a control electrode plate contact 1290 to be bonded to the control electrode plate 240. The main substrate 810 may further have an electrode plate contact to be bonded to the sub-electrode plate 250. A conductive through via and the U wiring 814 may electrically connect the U terminal and the first main electrode plate contact 1280, and the P wiring 812 may electrically connect the P terminal and the second main electrode plate contact 1285.

In S1130 of FIG. 11, the at least one semiconductor device 200 may first be connected to the back surface of the main substrate 810. In other words, the first main electrode plate 220, the second main electrode plate 230, the control electrode plate 240, and the sub-electrode plate 250 of each semiconductor device 200 are each connected to a corresponding electrode on the back surface of the main substrate 810, which is the first main electrode plate contact 1280 for the first main electrode plate 220, the second main electrode plate contact 1285 for the second main electrode plate 230, or the control electrode plate contact 1290 for the control electrode plate 240 in this figure, by, for example, a nano-silver paste or gold-to-gold direct bonding.

Then, the heat radiator 830 may be attached to a surface, on a side opposite to the main substrate 810, of the at least one semiconductor device 200. The semiconductor device 200 and the heat radiator 830 may be directly crimped together or may be in contact with each other via a thermal conductive material. The thermal conductive material may be paste thermal conductive grease or filler, a heat conduction sheet or heat dissipation sheet, or any other TIM or Thermal Interface Material. The semiconductor device 200 and the heat radiator 830 may be crimped together while the thermal conductive material is provided on one or both of the semiconductor device 200 or the heat radiator 830. As illustrated in this figure, the mounting substrate 210 of the semiconductor device 200 may have a heat conductor plate 1270 formed on a surface, on a side opposite to the mounting surface for the switching element 10, of the insulating substrate 500. The heat conductor plate 1270 may be a thermal conductive part having a higher thermal conductivity than the insulating substrate 500, such as a copper plate.

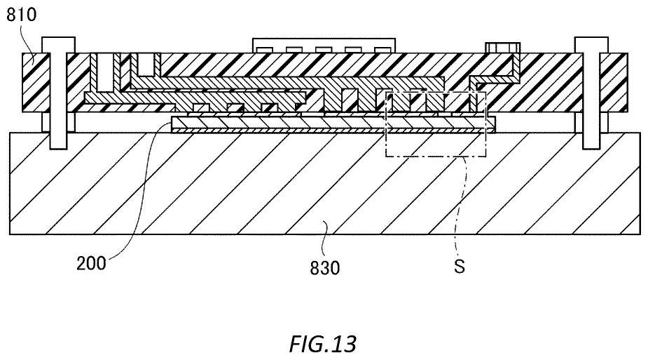

FIG. 13 is a schematic view of a cross-section of the semiconductor module 800 according to the present embodiment. In the process of S1130 in FIG. 11, the main substrate 810 may be fastened to the heat radiator 830 by screwing a screw into a screw hole provided in a surface of the heat radiator 830 so that the screw penetrates the main substrate 810 to reach an area where the semiconductor device 200 is not positioned on the surface of the heat radiator 830, as in the example of this figure. The semiconductor module 800 may be sold and used in the configuration illustrated in this figure or may be sold and used in a configuration in which the area between the main substrate 810 and the heat radiator 830 is encapsulated by, for example, resin encapsulation.

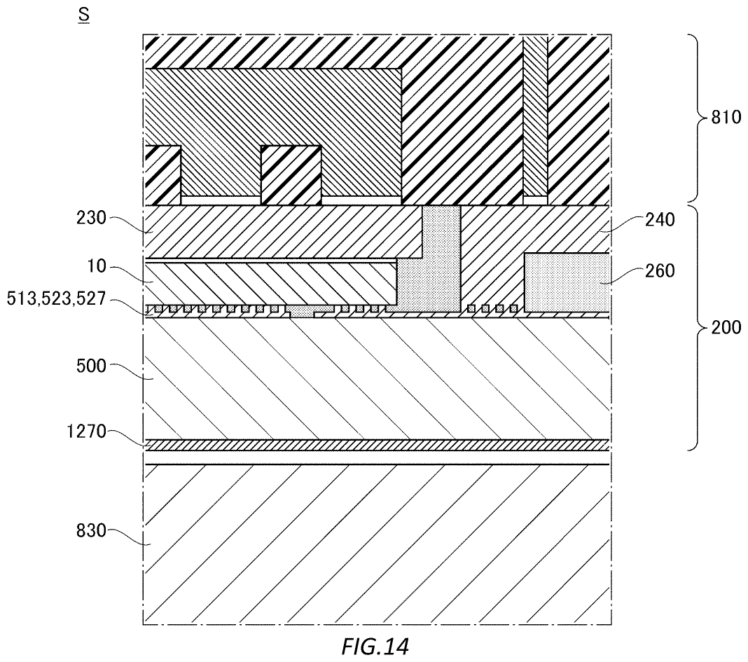

FIG. 14 is a schematic view in which a region S illustrated in FIG. 13 is enlarged. The electrode plate such as the second main electrode plate 230 and the control electrode plate 240 in the semiconductor device 200 is electrically connected to each terminal on the front surface of the main substrate 810 or the control device 820 via each electrode contact and each wiring of the main substrate 810. The semiconductor module 800 can be downsized or made thinner by connecting the switching element 10 and each terminal such as the P terminal by the inner layer wiring of the main substrate 810 at a relatively small wiring distance. The semiconductor module 800 can reduce inductance between the first main electrode plate 220 and the second main electrode plate 230 of the semiconductor device 200 and each terminal, which is also illustrated as “main circuit inductance”, and inductance between the control electrode plate 240 and the sub-electrode plate 250 of the semiconductor device 200 and the control device 820, which is also illustrated as “gate control circuit inductance”.

In the semiconductor module 800, the second main electrode plate 230 is bonded to a surface on a side with the second main electrode 120 of the switching element 10, which is a surface on an upper side in the figure, and the second main electrode plate 230 is electrically connected to, for example, the P terminal on the front surface of the main substrate 810 via, for example, the wiring within the main substrate 810. Here, such an electrical connection path is formed of a metal material also having a high thermal conductivity such as copper. Therefore, the semiconductor module 800 can convey heat from a surface on a side with the second main electrode 120 of the switching element 10 to, for example, each terminal through the wiring pattern within the main substrate 810 to dissipate the heat to, for example, a bus bar connected to each terminal.

The surface on a side with, for example, the first main electrode 100 and the control electrode 110 of the switching element 10, which is a surface on a lower side in the figure, is electrically connected to, for example, the first main electrode contact 513 of the first main electrode wiring 510 and the control electrode contact 523 of the control wiring 520 formed on a side with the mounting surface for the switching element 10 in the insulating substrate 500. The semiconductor module 800 can convey heat from a surface on a side of, for example, the control electrode 110 of the switching element 10 to the heat radiator 830 via the first main electrode wiring 510 and the control wiring 520, the insulating substrate 500, and the heat conductor plate 1270 to dissipate the heat from the heat radiator 830.

As a variant of the present embodiment, the semiconductor device 200 (UU1) and the semiconductor device 200 (UD1) among the semiconductor devices 200 illustrated in FIG. 10 may be constructed as a 2 in 1 module, on which an upper arm and a lower arm for one phase are mounted in an assembly with the main substrate 810 for wiring the two semiconductor device 200. A 6 in 1 module may be constructed for upper arms and lower arms for three phases. In this case, a number of the semiconductor devices 200 constituting the upper arms and the lower arms is not limited to one. In this case, although the semiconductor device 200 is formed to be separate semiconductor devices 200 by, for example, dicing after the process of S350 as illustrated in FIG. 3, the semiconductor devices 200 constituting the 2 in 1 module or the 6 in 1 module may be integrally formed without dicing.

As an inverter device in another variant of the present embodiment, a smoothing capacitor not shown in the semiconductor module of FIG. 8 may be connected to the P terminal and the N terminal, and at least two of the U terminal, the V terminal, and the W terminal may each include a current sensor not shown. The current sensor may be mounted on the main substrate 810, may be mounted on a distinct substrate not shown, or may be provided in the inner layer of the main substrate 810. When the current sensor is mounted on the main substrate 810, a magnetic shield plate may be provided as needed in at least a part of the surroundings of the current sensor. The magnetic shield plate may be implemented to be inserted into a slit provided in the main substrate 810 or may be implemented as, for example, a pattern in the inner layer of the main substrate 810.

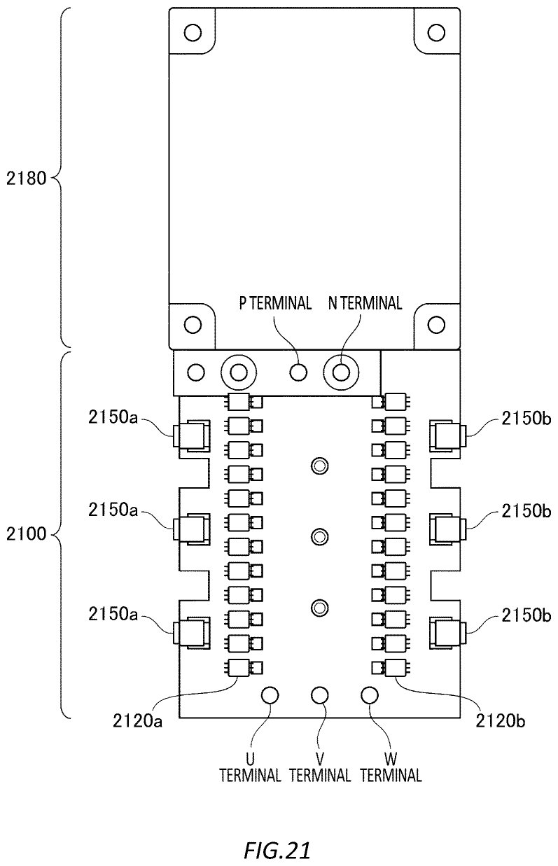

A connection between the smoothing capacitor and the main substrate 810 may be implemented by connecting a terminal of the smoothing capacitor to a terminal for connecting provided on the main substrate 810. An example of such a connection of the smoothing capacitor includes those described below with reference to FIG. 21. The heat radiator 830 in FIG. 8 may be provided individually for at least one semiconductor device 200 or may be provided individually for all the semiconductor devices 200.

The semiconductor module 800 in FIG. 8 may include a temperature sensor not shown. The temperature sensor may be mounted on the main substrate 810 or may be provided in the inner layer of the main substrate 810. By providing the temperature sensor in the inner layer of the main substrate 810, a temperature of the semiconductor device 200 can be more accurately measured.

The semiconductor module 800 in FIG. 8 may include a gate resistance not shown. The gate resistance is connected in series to the control wiring between the control electrode plate 240 of the semiconductor device 200 and the control device 820. The gate resistance may be mounted on the main substrate 810 or may be provided in the inner layer of the main substrate 810. By providing the gate resistance in the inner layer of the main substrate 810, the gate resistance can be arranged in an immediate vicinity of the semiconductor device 200, so that fluctuation of a voltage generated in the control electrode 110 of the semiconductor device 200 can be reduced.

The semiconductor module 800 in FIG. 8 may include a snubber capacitor not shown. The snubber capacitor may be mounted on the main substrate 810 or may be provided in the inner layer of the main substrate 810. By providing the snubber capacitor in the inner layer of the main substrate 810, the snubber capacitor can be arranged in the immediate vicinity of the semiconductor device 200, so that a high voltage transiently generated when switching the semiconductor device 200 can be further suppressed.

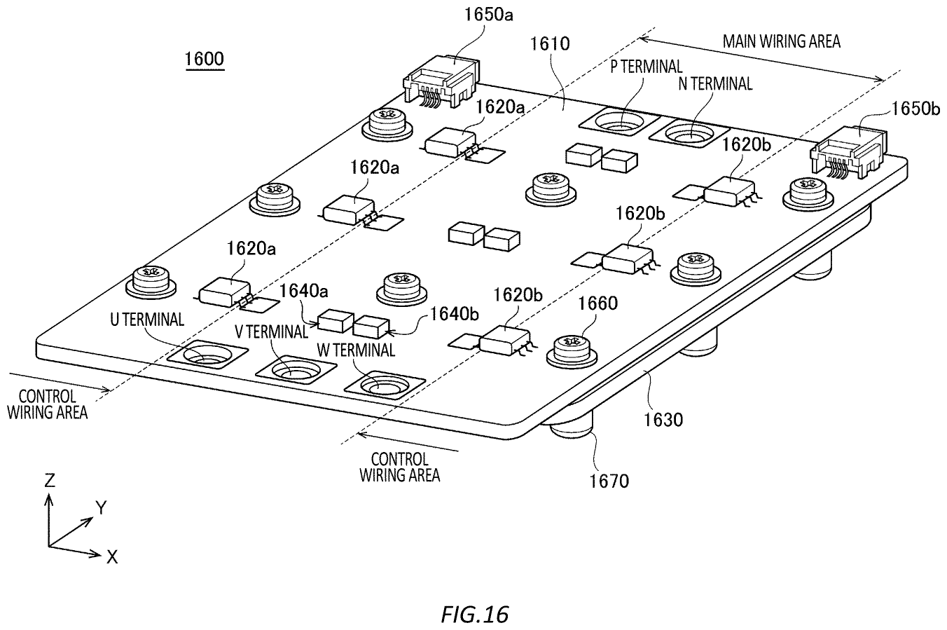

An external control apparatus which generates a signal for controlling at least the control device and which is not shown may be provided in the semiconductor module 800 in FIG. 8 so as to cover at least a part of the front surface of the main substrate 810. The control signal thus generated is input to the control device via a control connector as described below with reference to FIG. 16.

The control device 820 mounted on the main substrate 810 in FIG. 8 may be mounted at a position according to a distribution of heat generation of the semiconductor device 200. As an example, a surface of the main substrate 810 corresponding to immediately above the semiconductor device 200 is avoided. A slit may be provided in the main substrate 810 in the surroundings of the control device 820 so as to mitigate an influence of the temperature upon mounting.

The control device 820 mounted on the main substrate 810 in FIG. 8 may be mounted at a position according to a wiring path of the main wiring. As an example, each control device 820 may be arranged by avoiding a position corresponding to immediately above each main wiring, which may be the P wiring 812, the N wiring 813, the U wiring 814, the V wiring 815, and the W wiring 816, on the front surface of the main substrate 810. This can prevent malfunctioning of the control device 820 due to an influence of a noise generated by a large current flowing through the main wiring.

The main substrate 810 in FIG. 8 may have another heat radiator provided on a surface of the main substrate 810 on a side opposite to the side on which the heat radiator 830 is arranged. In this case, the another heat radiator may be a heat capacity body separate from the heat radiator 830.

FIG. 15 is a perspective view of a semiconductor device 1500 according to a first variant of the present embodiment. Because the semiconductor device 1500 is a variant of the semiconductor device 200 illustrated in, for example, FIGS. 1 to 7, a description thereof is omitted below except for a difference therebetween. The semiconductor device 1500 may have a size the same as that of the semiconductor device 200 or may have a size similar to the semiconductor device 200. The semiconductor device 1500 has a structure in which each electrode plate electrically connected to each electrode of the switching element such as the switching element 10 illustrated in FIG. 1 is exposed to one surface of the plate-shaped semiconductor device 1500. Although the switching element 10 is used as the switching element in the description of the present variant, the semiconductor device 1500 may have a switching element other than the switching element 10 mounted thereon.

In the present variant, the semiconductor device 1500 includes a mounting substrate 1510, a first main electrode plate 1520, a second main electrode plate 1530, a sub-electrode plate 1550, a control electrode plate 1540, and an encapsulating portion 1560. The first main electrode plate 1520, the second main electrode plate 1530, the sub-electrode plate 1550, and the control electrode plate 1540 are provided on one surface of the semiconductor device 1500, which is a surface on an upper side in the figure. The semiconductor device 1500 may have a structure in which the second main electrode plate 1530 is arranged between the first main electrode plate 1520 and the control electrode plate 1540 on the one surface.

The mounting substrate 1510 has the switching element such as the switching element 10 mounted on the mounting surface, which is a surface on an upper side in the figure. The mounting substrate 1510 corresponds to the mounting substrate 210 of the semiconductor device 200. The mounting substrate 1510 may have the switching element 10 mounted thereon by bonding a surface on a side with the second main electrode 120 in the switching element 10 to the mounting surface of the mounting substrate 1510. The mounting substrate 1510 may have a pattern of wiring and an electrode contact different from those of the mounting substrate 210 according to a difference in an orientation in which the switching element 10 is mounted.

The first main electrode plate 1520 is electrically connected to the second main electrode 120 of the switching element 10. The first main electrode plate 1520 corresponds to the first main electrode plate 220 of the semiconductor device 200. The second main electrode plate 1530 is electrically connected to the first main electrode 100 of the switching element 10. The second main electrode plate 1530 corresponds to the second main electrode plate 230 of the semiconductor device 200. In the present variant, the second main electrode plate 1530 is bonded to the first main electrode 100 in an area where the first main electrode 100 is formed on a surface on a side of the switching element 10 with the first main electrode 100. The second main electrode plate 1530 may have a nick avoiding a position above an area where the control electrode 110 is formed on the surface on the side of the switching element 10 with the first main electrode 100. Except for a middle portion on a far side in the figure adjacent to the control electrode plate 1540, the second main electrode plate 1530 may be extended to a side, opposite to a side with first main electrode plate 1520, of the semiconductor device 1500, which is the far side in the figure, and this portion thus extended may be used as the sub-electrode plate 1550. The sub-electrode plate 1550 corresponds to the sub-electrode plate 250 of the semiconductor device 200.

The control electrode plate 1540 is electrically connected to the control electrode 110 of the switching element 10. The control electrode plate 1540 corresponds to the control electrode plate 240 of the semiconductor device 200. The control electrode plate 1540 is bonded to the control electrode 110 in an area where the control electrode 110 is formed on the surface on the side of the switching element 10 with the first main electrode 100. The control electrode plate 1540 may be extended to a side, opposite to a side with the first main electrode plate 1520, of the semiconductor device 1500, which is the far side in the figure. The encapsulating portion 1560 covers the mounting surface for the switching element 10 in the mounting substrate 1510 while exposing the first main electrode plate 1520, the second main electrode plate 1530, and the control electrode plate 1540.

Here, while the semiconductor device 200 has a structure in which the second main electrode plate 230 connected to the second main electrode 120 of the switching element 10 is arranged between the first main electrode plate 220 connected to the first main electrode 100 of the switching element 10 and the control electrode plate 240 connected to the control electrode 110 of the switching element 10, the semiconductor device 1500 may have a structure in which the second main electrode plate 1530 connected to the first main electrode 100 of the switching element 10 is arranged between the first main electrode plate 1520 connected to the second main electrode 120 of the switching element 10 and the control electrode plate 1540 connected to the control electrode 110 of the switching element 10. In this case, the first main electrode plate 220 and the second main electrode plate 230 of the semiconductor device 200 and the first main electrode plate 1520 and the second main electrode plate 1530 of the semiconductor device 1500 have inverted polarities to each other for the main electrode of the switching element 10. For example, when the first main electrode plate 220 of the semiconductor device 200 is a source and the second main electrode plate 230 is a drain, the first main electrode plate 1520 of the semiconductor device 1500 is a drain and the second main electrode plate 1530 is a source. By using the semiconductor device 200 and the semiconductor device 1500 having such different electrode arrangements, the semiconductor device having a more appropriate electrode arrangement can be selectively used according to a mounting position of each semiconductor device in the semiconductor module 800 or another semiconductor module.

For convenience of description, for example, when focused on an arrangement of the semiconductor device, among the main electrodes of the switching element such as the switching element 10 mounted on the semiconductor device 1500, the main electrode connected to the first main electrode plate 1520 may be illustrated as the first main electrode and the main electrode connected to the second main electrode plate 1530 may be illustrated as the second main electrode. For example, when the first main electrode 100 of the switching element 10 is connected to the second main electrode plate 1530 and the second main electrode 120 of the switching element 10 is connected to the first main electrode plate 1520, for convenience of description, the first main electrode 100 of the switching element 10 is also illustrated as the second main electrode and the second main electrode 120 of the switching element 10 is also illustrated as the first main electrode.

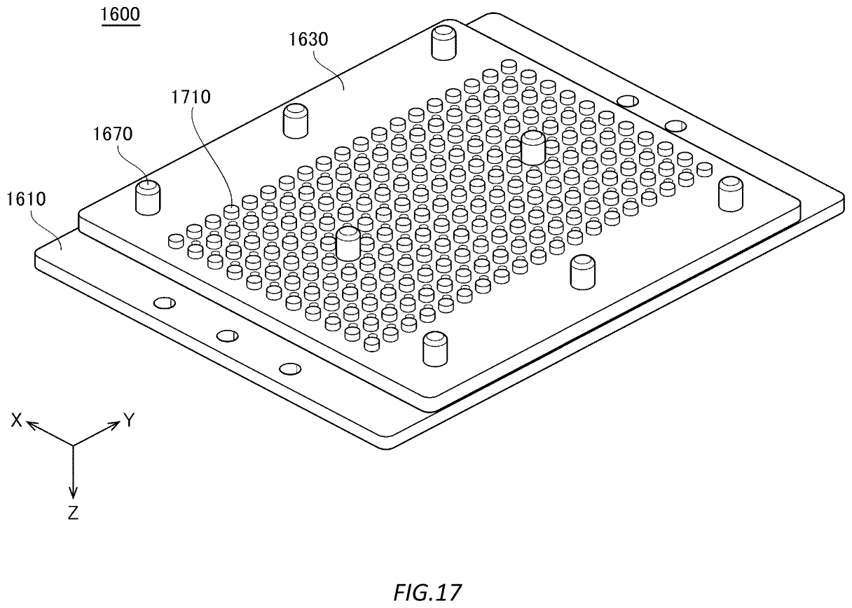

FIG. 16 is a perspective view of a semiconductor module 1600 according to a second variant of the present embodiment. FIG. 17 is a view of the semiconductor device 1600 according to the second variant of the present embodiment when viewed from a side with a heat radiator 1630. Because the semiconductor module 1600 is a variant of the semiconductor module 800 illustrated in FIGS. 8 to 14, a description thereof is omitted below except for a difference therebetween. The semiconductor module 1600 includes one or more semiconductor devices 200, a main substrate 1610, one or more control devices 1620, one or more snubber capacitors 1640, one or more control connectors 1650, a heat radiator 1630, and a fastening member 1660.

Similarly to the semiconductor module 800, the semiconductor module 1600 according to the present variant is an inverter device. In the examples of FIGS. 16 and 17, the semiconductor module 1600 is a three-phase inverter. For each phase, one semiconductor device 200 is allocated to an upper arm and one semiconductor device 200 is allocated to a lower arm. Therefore, the semiconductor module 1600 includes six, which is calculated by three phases * (one for the upper arm and one for the lower arm), semiconductor devices 200. Similarly to the semiconductor module 800 illustrated in FIG. 8 and FIG. 9, the semiconductor module 1600 has a structure in which a plurality of semiconductor devices 200 is sandwiched between the main substrate 1610 and the heat radiator 1630. Thus, the plurality of semiconductor devices 200 are not shown in FIG. 16 and FIG. 17.

The semiconductor module 1600 may include a semiconductor device 200 for one phase, a semiconductor device 200 for two phases, or a semiconductor device 200 for any number of phases, and may include one or two or more semiconductor devices 200 for each arm for each phase. The semiconductor module 1600 may have any circuit configuration using, for example, the semiconductor device 200 such as 3-level inverter or multi-level inverter having one or more phases, or diode bridge, or may include any number of semiconductor devices 200 according to its application. The semiconductor module 1600 may have the semiconductor device 1500 mounted thereon instead of the semiconductor device 200 as at least some of the semiconductor devices.

The main substrate 1610 corresponds to the main substrate 810 of the semiconductor module 800. The first main electrode plate 220, the second main electrode plate 230, and the control electrode plate 240 of the at least one semiconductor device 200 are connected to a back surface of the main substrate 1610. When the semiconductor module 1600 has the at least one semiconductor device 1500 mounted thereon, the first main electrode plate 1520, the second main electrode plate 1530, and the control electrode plate 1540 of at least one semiconductor device 1500 are connected to the back surface of the main substrate 1610.

Three semiconductor devices for an upper arm among the semiconductor devices such as the semiconductor devices 200 and the semiconductor devices 1500, which are also illustrated as “first semiconductor devices” are arranged in positions corresponding to an extent between three control devices 1620a and three snubber capacitor 1640a, which are three snubber capacitors 1640 on a left-hand side among six snubber capacitors 1640 in the figure, on the back surface of the main substrate 1610. Therefore, the three semiconductor devices for the upper arms are arrayed in a line in a Y direction in the figure on the back surface of the main substrate 1610.

Three semiconductor devices for lower arms, which is also illustrated as “second semiconductor devices”, are arranged in positions corresponding to an extent between three control devices 1620b and three snubber capacitors 1640b, which are three snubber capacitors 1640 on a right-hand side among the six snubber capacitors 1640 in the figure, on the back surface of the main substrate 1610. Therefore, the three semiconductor devices for the lower arms are arrayed, on the back surface of the main substrate 1610, in a line in a Y direction in the figure side by side with three semiconductor devices for the upper arm.

The main substrate 1610 has a P terminal and an N terminal in a vicinity of an edge on a far side in the Y direction in the figure on the front surface. The main substrate 1610 has a U terminal, a V terminal, and a W terminal in a vicinity of an edge, on a side opposite to the edge where the P terminal and the N terminal are provided, on the front surface. The P terminal, the N terminal, the U terminal, the V terminal, and the W terminal may have a through aperture into which, for example, a bolt can be inserted for fastening, for example, a wiring cable or bus bar for a large current to each terminal.

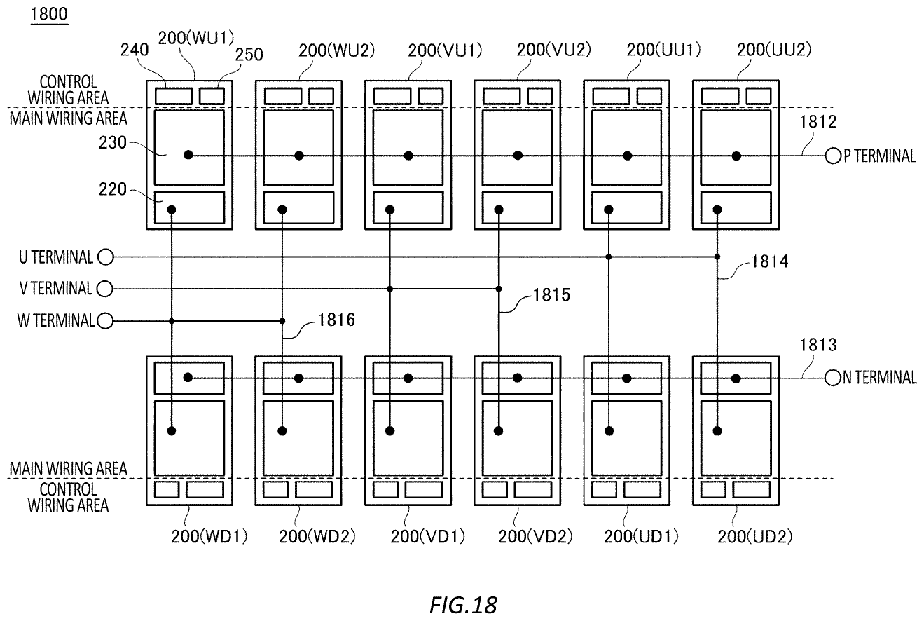

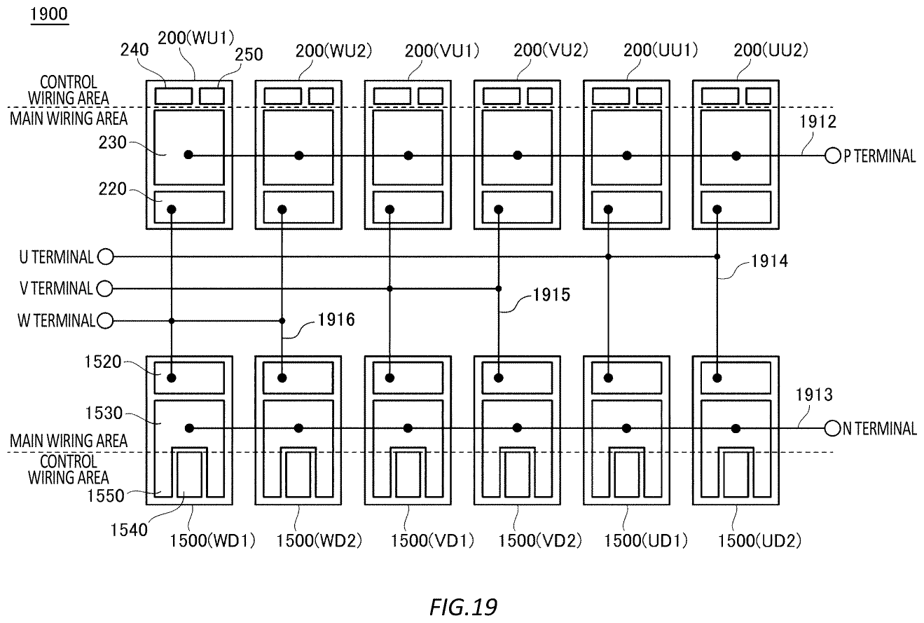

The P wiring between the P terminal and each semiconductor device 200, the N wiring between the N terminal and each semiconductor device 200, the U wiring between the U terminal and a U-phase semiconductor device 200, the V wiring between the V terminal and a V-phase semiconductor device 200, and the W wiring between the W terminal and a W-phase semiconductor device 200 are provided within a range or an area corresponding to an extent between the three control devices 1620a and the three control devices 1620b in the X direction within the main substrate 1610, and extend in the Y direction. The area corresponding to an extent between the line of the three semiconductor devices 200 for the upper arms and the line of the semiconductor devices 200 for the lower arms in the main substrate 1610 are illustrated as a “main wiring area”. The main wiring area may be an area extending from an edge on a side with the U terminal, the V terminal, and the W terminal to an edge on a side with the P terminal and the N terminal in a range between the line of the three first semiconductor devices 200 for the upper arms and the line of the three second semiconductor devices 200 for the lower arms in the rectangular main substrate 1610. The main wiring area will be further described below by using the example of FIG. 18 and FIG. 19.

The one or more control devices 1620 are mounted on the front surface of the main substrate 1610. The control devices 1620 correspond to the control devices 820 of the semiconductor module 800. Each of the one or more control devices 1620 is electrically connected to the control electrode plate 240 and the sub-electrode plate 250 of each of the one or more semiconductor devices 200 via the wiring within the main substrate 1610. The control device 1620 controls the semiconductor device 200 by controlling a voltage of the control electrode plate 240 relative to the sub-electrode plate 250 of the semiconductor device 200. Each control device 1620 may control one semiconductor device 200 by being connected to the one semiconductor device 200, and may control two or more semiconductor devices 200 by being connected to the two or more semiconductor devices 200. The control device 1620 which controls one or two or more semiconductor devices 1500 may be electrically connected to the control electrode plate 1540 and the sub-electrode plate 1550 of each semiconductor device 1500 via wiring within the main substrate 1610.

In the present variant, each of the three control devices 1620a, which is also illustrated as a “first control device 1620a” controls each of the three first semiconductor devices 200 for the upper arms. The three first control devices 1620a are arranged, on the front surface of the semiconductor module 1600, side by side in the Y direction farther from the three first semiconductor devices 200 for the upper arms than the three second semiconductor devices 200 for the lower arm, that is, on a left-hand side in the X direction in the figure. An area where each first control device 1620a is arranged for controlling the upper arm, adjacent to a side with the first semiconductor devices 200 for the upper arms relative to the main wiring area when viewed from top, on the main substrate 1610 is illustrated as a “first control wiring area”. The first control wiring area may be an area reaching an edge extending in the Y direction positioned on the left-hand side in the X direction than the main wiring area, which is an edge on a left-hand side in the X direction, on the rectangular main substrate 1610. The first control wiring area will be further described below by using the example of FIG. 18 and FIG. 19.

Each of the three control devices 1620b, which is also illustrated as a “second control device 1620b”, controls each of the three second semiconductor devices 200 for the lower arm. The three second control devices 1620b are arranged, on the front surface of the semiconductor module 1600, side by side in the Y direction farther from the three second semiconductor devices 200 for the lower arms than the three first semiconductor devices 200 for the upper arm, that is, on a right-hand side in the X direction in the figure. An area where each second control device 1620b is arranged for controlling the lower arm, adjacent to a side with the second semiconductor device 200 for the lower arms relative to the main wiring area when viewed from top, on the main substrate 1610 is illustrated as a “second control wiring area”. The second control wiring area may be an area reaching an edge extending in the Y direction positioned on the right-hand side in the X direction than the main wiring area, which is an edge on a right-hand side in the X direction, on the rectangular main substrate 1610. The second control wiring area will be further described below by using the example of the FIG. 18 and FIG. 19.

The plurality of snubber capacitors 1640 are arranged in the main wiring area on the front surface of the main substrate 1610. Each of the at least one snubber capacitor 1640a, which is also illustrated as a “first snubber capacitor 1640a”, may be provided corresponding to each phase of the upper arms. In the present variant, three snubber capacitors 1640a are provided corresponding to three phases of the upper arms. The three snubber capacitors 1640a may be provided above the P wiring within the main substrate 1610. Each snubber capacitor 1640a is connected in parallel to a corresponding semiconductor device 200 between the P wiring and the output wiring for a corresponding phase among the U wiring, the V wiring, or the W wiring to suppress transient generation of a high voltage when switching the corresponding semiconductor device 200.

Each of the at least one snubber capacitor 1640b, which is also illustrated as a “second snubber capacitor 1640b”, may be provided corresponding to each phase of the lower arms. In the present variant, three snubber capacitors 1640b are provided corresponding to three phases of the lower arms. The three snubber capacitors 1640b may be provided above the N wiring within the main substrate 1610. Each snubber capacitor 1640b is connected in parallel to a corresponding semiconductor device 200 between the N wiring and the output wiring for a corresponding phase among the U wiring, the V wiring, or the W wiring to suppress transient generation of a high voltage when switching the corresponding semiconductor device 200.

Each snubber capacitor may be connected to an extent between the P wiring and the N wiring for a corresponding arm. The snubber capacitor can suppress transient generation of a high voltage when switching the corresponding semiconductor device 200 by using such a connecting method.

The at least one control connector 1650 is mounted on the front surface of the main substrate 1610 and is electrically connected to the at least one control device 1620. The semiconductor module 1600 is electrically connected to an external control apparatus via a cable detachably connected to the at least one control connector 1650. The at least one control device 1620 may control the one or more semiconductor devices 200 by receiving a control signal from the external control apparatus via the cable and the at least one control connector 1650.

In the present variant, at least one control connector 1650a, which is also illustrated as a “first control connector 1650a”, is arranged in the first control wiring area on the front surface of the main substrate 1610, and is electrically connected to at least one first control device 1620a. At least one control connector 1650b, which is also illustrated as a “second control connector 1650b”, is arranged in a second control wiring area on the front surface of the main substrate 1610, and is electrically connected to at least one second control device 1620b.

The heat radiator 1630 is provided on the back surface of the main substrate 1610 to which at least one semiconductor device 1500 is connected. The heat radiator 1630 may be in contact with a surface, on a side opposite to the main substrate 1610, of the one or more semiconductor devices 200. The heat radiator 1630 corresponds to the heat radiator 830 in the semiconductor module 800. The heat radiator 1630 may be a heat spreader, a heat sink, or a liquid-cooling heat exchanger.

In the present variant, the heat radiator 1630 has a structure in which, relative to a plate-shaped member, which is a body portion of the heat radiator 1630, having a surface on a side with the main substrate 1610 and the at least one semiconductor device 1500, one or more protruding members 1670 and one or more protruding members 1710 are provided on a surface opposite to the side with the main substrate 1610 and the at least one semiconductor device 1500 in the plate-shaped member. The plate-shaped member of the heat radiator 1630 may have such a size that does not cover the P terminal, the N terminal, the U terminal, the V terminal, and the W terminal on the back surface of the main substrate 1610.

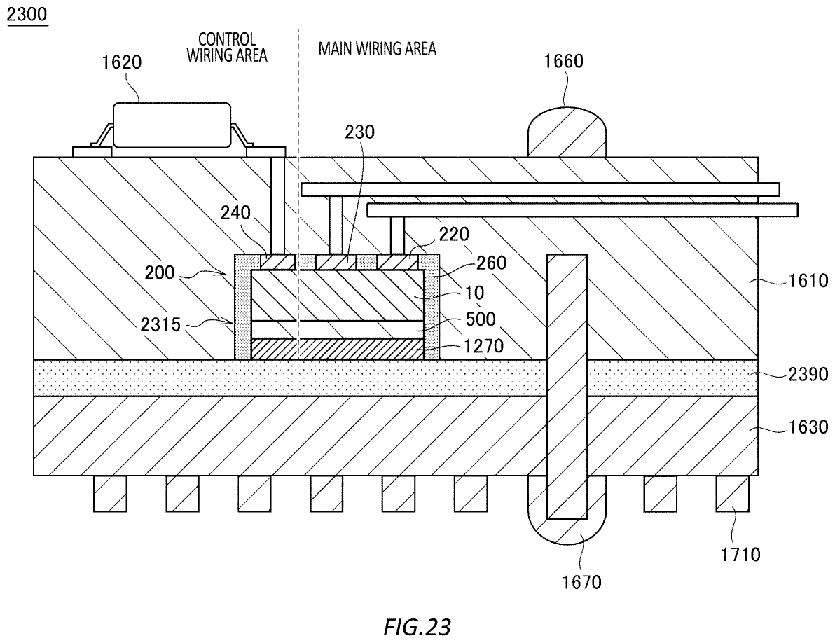

Each of the one or more protruding members 1670 is a protrusion having a cylindrical shape or any other shape protruding from a surface opposite to a side with the main substrate 1610 in the plate-shaped member of the heat radiator 1630. The protruding member 1670 is fastened to the main substrate 1610 by a fastening member 1660 penetrating a plate-shaped member of the heat radiator 1630 from the front surface of the main substrate 1610 to the protruding member 1670. Thus, the heat radiator 1630 is fastened to the back surface of the main substrate 1610. This will be described below by using the example of FIG. 23.

At least some of the plurality of protruding members 1670, which are six protruding members 1670 in the example of this figure, are arrayed along edges in the Y direction positioned on right and left sides in the X direction in the figure on the heat radiator 1630. Some other of the plurality of protruding members 1670, which are two protruding members 1670 in the example of this figure, are arrayed along an edge in the Y direction within a middle portion in the X direction in the figure on the heat radiator 1630.

Each of the one or more protruding members 1710 is a protrusion having a cylindrical shape or any other shape protruding from a surface opposite to the side with the main substrate 1610 in the plate-shaped member of the heat radiator 1630. The protruding member 1670 may not have a function of being fastened to the main substrate 1610 by, for example, the fastening member 1660. The plurality of protruding members 1710 may be arranged in a range corresponding to the main wiring area of the main substrate 1610.

Each protruding member 1670 and each protruding member 1710 increase efficiency of heat dissipation by increasing a surface area of the heat radiator 1630. Here, a surface where each protruding member 1670 and each protruding member 1710 are provided in the heat radiator 1630 may be in contact with a gas or liquid coolant or may be exposed within a flow path of the coolant.

FIG. 18 illustrates a connection of each wiring within a semiconductor module 1800 according to a third variant of the present embodiment. Because the present variant is a variant of the connection structure of each wiring within the semiconductor module 800 illustrated in FIG. 10, a description thereof is omitted below except for a difference therebetween. In the semiconductor module 800 illustrated in FIG. 10, the semiconductor devices 200 for 6 sets of the upper and lower arms are arrayed in an order of the U-phase, the V-phase, the W-phase, the U-phase, the V-phase, and the W-phase from a left-hand side of FIG. 10. In contrast, in the semiconductor module 1800 illustrated in FIG. 18, the 6 sets of the semiconductor devices 200 for the upper and lower arms are arrayed so that upper and lower two of the semiconductor devices 200 corresponding to each phase are arranged adjacent to each other in an order of the W-phase, the W-phase, the V-phase, the V-phase, the U-phase, and the U-phase from the left-hand side in FIG. 18.

For the U-phase, the at least one semiconductor device 200 includes at least one first semiconductor device 200 (UU1, UU2) and at least one second semiconductor device 200 (UD1, UD2). The at least one first semiconductor device 200 (UU1, UU2) is a semiconductor device 200 for the upper arm, which is the semiconductor device 200 on an upper side in the figure, and the at least one second semiconductor device 200 (UD1, UD2) is the semiconductor device 200 for the lower arm, which is the semiconductor device 200 on a lower side in the figure. The at least one first semiconductor device 200 for the U-phase is also illustrated as first at least one first semiconductor device 200. The at least one second semiconductor device 200 for the U-phase is also illustrated as first at least one second semiconductor device 200.

Similarly, for the V-phase, the at least one semiconductor device 200 includes at least one first semiconductor device 200 (VU1, VU2) and at least one second semiconductor device 200 (VD1, VD2). The at least one first semiconductor device 200 for the V-phase is also illustrated as second at least one first semiconductor device 200. The at least one second semiconductor device 200 for the V-phase is also illustrated as second at least one second semiconductor device 200.

Similarly, for the W-phase, the at least one semiconductor device 200 includes at least one first semiconductor device 200 (WU1, WU2) and at least one second semiconductor device 200 (WD1, WD2). The at least one first semiconductor device 200 for the W-phase is also illustrated as third at least one first semiconductor device 200. The at least one second semiconductor device 200 for the W-phase is also illustrated as third at least one second semiconductor device 200.

Each first semiconductor device 200 for the U-phase, the V-phase, and the W-phase is arrayed in a line on the back surface of the main substrate 1610. Each second semiconductor device 200 for the U-phase, the V-phase, and the W-phase is arrayed in a line side by side with the line of the first semiconductor device 200 on the back surface of the main substrate 1610.

In the present variant, on the back surface of the main substrate 1610, each of the at least one first semiconductor device 200 and a corresponding second semiconductor device 200 among the at least one second semiconductor device 200 are arranged in an orientation so that the first main electrode plates 220 oppose each other. Thus, in the semiconductor module 1800, the control electrode plate 240 and the sub-electrode plate 250 connected to the control wiring can be arranged on an side opposite to the opposing semiconductor devices 200, so that the control wiring can be easily arranged away from the main wiring such as the P wiring 1812, the N wiring 1813, the U wiring 1814, the V wiring 1815, and the W wiring 1816 through which a main current flows. For example, for convenience of mounting, on the back surface of the main substrate 1610, each of the at least one first semiconductor device 200 and a corresponding second semiconductor device 200 among the at least one second semiconductor device 200 may be arranged in an orientation so that the first main electrode plate 220 and the control electrode plate 240 oppose each other.

The main electrode plate on a positive side, which is the second main electrode plate 230 as a drain in the example of this figure, among the first main electrode plate 220 and the second main electrode plate 230 of each of at least one first semiconductor device 200 (UU1, UU2, VU1, VU2, WU1, WU2) for each phase is connected to the P terminal via the P wiring 1812 within the main substrate 1610. The main electrode plate on a negative side, which is the first main electrode plate 220 as a source, among the first main electrode plate 220 and the second main electrode plate 230 of each of the at least one second semiconductor device 200 (UD1, UD2, VD1, VD2, WD1, WD2) for each phase is connected to the N terminal via the N wiring 1813 within the main substrate 1610. The main electrode plate on the negative side, which is the first main electrode plate 220 as the source, among the first main electrode plate 220 and the second main electrode plate 230 of each of the at least one first semiconductor device 200 for each phase is electrically connected to the main terminal plate on the positive side, which is the second main electrode plate 230 as the drain, among the first main electrode plate 220 and the second main electrode plate 230 of a corresponding second semiconductor device 200 among the at least one second semiconductor device 200.

For the U-phase, the main electrode plate on a negative side, which is the first main electrode plate 220 as the source, among the first main electrode plate 220 and the second main electrode plate 230 of the at least one first semiconductor device 200 (UU1, UU2) and the main electrode plate on a positive side, which is the second main electrode plate 230 as the drain, among the first main electrode plate 220 and the second main electrode plate 230 of the at least one second semiconductor device 200 (UD1, UD2) are connected to the U terminal as a first output terminal, via the U wiring 1814 as a first output wiring within the main substrate 1610. For the V-phase, the main electrode plate on a negative side, which is the first main electrode plate 220 as the source, among the first main electrode plate 220 and the second main electrode plate 230 of the at least one first semiconductor device 200 (VU1, VU2) and the main electrode plate on a positive side, which is the second main electrode plate 230 as the drain, among the first main electrode plate 220 and the second main electrode plate 230 of the at least one second semiconductor device 200 (VD1, VD2) are connected to the V terminal as a second output terminal, via the V wiring 1815 as a second output wiring within the main substrate 1610. For the W-phase, the main electrode plate on a negative side, which is the first main electrode plate 220 as the source, among the first main electrode plate 220 and the second main electrode plate 230 of the at least one first semiconductor device 200 (WU1, WU2) and the main electrode plate on a positive side, which is the second main electrode plate 230 as the drain, among the first main electrode plate 220 and the second main electrode plate 230 of the at least one second semiconductor device 200 (WD1, WD2) are connected to the U terminal as the first output terminal, via the W wiring 1816 as a third output wiring within the main substrate 1610.

The P wiring 1812, the N wiring 1813, the U wiring 1814, the V wiring 1815, and the W wiring 1816 are provided in the main wiring area of the main substrate 1610 corresponding to an extent between the line of the first semiconductor devices 200 for the U-phase, the V-phase, and the W-phase and the line of the second semiconductor devices 200 for the U-phase, the V-phase, and the W-phase, when viewed from top. Here, when the control electrode plate 240 of each semiconductor device 200 is arranged on a side opposite to an opposing semiconductor device 200, the main wiring area may be an area including the first main electrode plate 220 and the second main electrode plate 230 of the semiconductor device 200. In contrast, the control device such as the control device 1620, and a most part of the control wiring from the control device to the control electrode plate 240 and the sub-electrode plate 250 of each semiconductor device 200 are provided in the control wiring area distinguished from the main wiring area. Thus, the semiconductor module 1800 can prevent a noise from being added to the control device and the control wiring within the control wiring area due to a large current flowing through the main wiring arranged in the main wiring area.

The semiconductor module 800 may have a connection structure of each wiring according to the present variant instead of the connection structure of each wiring illustrated in FIG. 10. The semiconductor module 1600 illustrated in FIGS. 16 to 17 may have a connection structure of each wiring in which the number of the semiconductor device 200 for each arm for each phase is one in this figure, that is, a structure in which each semiconductor device 200 of UU2, UD2, VU2, VD2, WU2, and WD2 is removed from the semiconductor module 1800.

FIG. 19 illustrates a connection of each wiring within a semiconductor module 1900 according to a fourth variant of the present embodiment. Because the semiconductor module 1900 according to the present variant is a variant of the semiconductor module 1800 illustrated in FIG. 18, a description thereof is omitted below except for a difference therebetween.

The semiconductor module 1900 includes the semiconductor device 1500 instead of the semiconductor device 200 as each semiconductor device for the lower arms. Similarly to the semiconductor module 1800, the second main electrode plate 230 on a positive side of each first semiconductor device 200 is connected to a P terminal via P wiring 1912 within the main substrate 1610. Because the main electrode plate on a negative side of each second semiconductor device 1500 is the second main electrode plate 1530, the second main electrode plate 1530 of each second semiconductor device 1500 is connected to an N terminal via N wiring 1913. Because the main electrode plate on a positive side of each second semiconductor device 1500 is the first main electrode plate 1520, the first main electrode plate 1520 of each second semiconductor device 1500 is connected to the first main electrode plate 220 of a corresponding first semiconductor device 200 and a U terminal, a V terminal, or a W terminal via U wiring 1914, V wiring 1915, or W wiring 1916.

According to the present variant, by constructing the upper and lower arms by using the semiconductor device 200 and the semiconductor device 1500, each main electrode plate of which having a polarity different from that of the semiconductor device 200, the output wiring such as the U wiring 1914, the V wiring 1915, and the W wiring 1916 are only required to connect the opposing first main electrode plate 220 and first main electrode plate 1520. Therefore, according to the present variant, a wiring length from the P wiring through the semiconductor devices for the upper and lower arms to the N wiring can be further shortened.

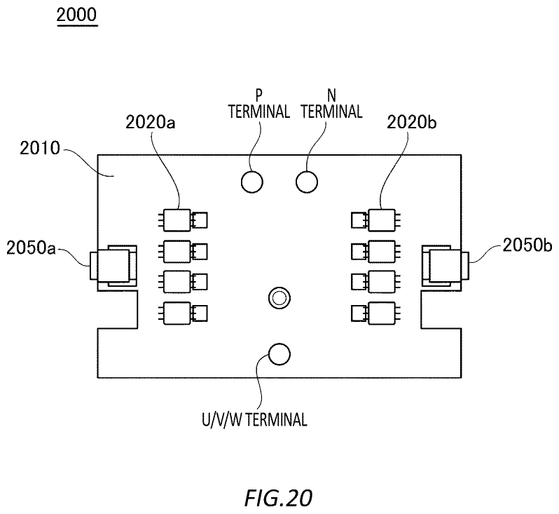

FIG. 20 illustrates a semiconductor module 2000 according to a fifth variant of the present embodiment. Because the present variant is a variant of the semiconductor module 1600 illustrated in FIGS. 16 to 17, a description thereof is omitted below except for a difference therebetween. A change similar to that in the present variant may be added to each of the semiconductor module 800 illustrated in FIGS. 8 to 9, the semiconductor module 1800 illustrated in FIG. 18, and the semiconductor module 1900 illustrated in FIG. 19. The semiconductor module 2000 includes one or more semiconductor devices 200, a main substrate 2010, one or more control devices 2020, and one or more control connectors 2050.

The semiconductor module 2000 according to the present variant includes a configuration corresponding to upper and lower arms for one phase in the inverter device. In the semiconductor module 2000, four semiconductor devices 200 are allocated to the upper arm and four semiconductor devices 200 are allocated to the lower arm. Instead of the above, the semiconductor module 2000 may include a number other than four, that is, any number of one, two, three or five, or more of semiconductor devices 200 for each of the upper arm and the lower arm. Similarly to the semiconductor module 1600 illustrated in FIGS. 16 to 17, the semiconductor module 2000 has a structure in which the plurality of semiconductor devices 200 are sandwiched between the main substrate 2010 and a heat radiator, not shown, on a back side in the figure. Thus, the plurality of semiconductor devices 200 are not shown in FIG. 20. Similar to the semiconductor module 1900 as an example, the semiconductor module 2000 may have a configuration in which some semiconductor devices 200 are each replaced with the semiconductor device 1500.

The main substrate 2010 corresponds to the main substrate 1610 of the semiconductor module 1600. On the back surface of the main substrate 2010, the four semiconductor devices 200 for the upper arm, which are the first semiconductor devices 200, are arrayed in a line side by side on a right-hand side relative to the four first control devices 2020a in the figure when viewed from top, and the four semiconductor devices 200 for the lower arm, which are the second semiconductor devices 200, are arrayed in a line side by side on a left-hand side relative to the four second control devices 2020b in the figure when viewed from top.

The main substrate 2010 has a P terminal and an N terminal in a vicinity of an edge on an upper side in the figure on the front surface. The main substrate 2010 has the output terminal in a vicinity of an edge, on a side opposite to the edge where the P terminal and the N terminal are provided, on the front surface. An output terminal may be used as the U terminal, the V terminal, the W terminal, or another terminal. P wiring between the P terminal and each semiconductor device 200 for the upper arm, N wiring between the N terminal and each semiconductor device 200 for the lower arm, and output wiring between the output terminal and each semiconductor device 200 are provided, when viewed from top, within the main wiring area corresponding to an extent between the four semiconductor devices 200 for the upper arm, which correspond to the right-hand side relative to the four control devices 2020a in the figure, and the four semiconductor devices 200 for the lower arm, which correspond to the left-hand side relative to the four control device 2020b in the figure, within the main substrate 2010, and extend in a vertical direction in the figure.

The plurality of control devices 2020 are mounted on the front surface of the main substrate 2010. The control devices 2020 correspond to the control devices 1620 of the semiconductor module 1600. In the present variant, each of the four control devices 2020a, which is the first control device 2020a, controls each of the four first semiconductor devices 200 for the upper arm. The four first control devices 2020a are arranged side by side in the vertical direction in the figure in the first control wiring area, adjacent to a side with the four first semiconductor devices 200 for the upper arm relative to the main wiring area when viewed from top, on the front surface of the main substrate 2010. Each of the four control devices 2020b, which is the second control device 2020b, controls each of the four second semiconductor devices 200 for the lower arm. The four second control devices 2020b are arranged side by side in the vertical direction in the figure in the second control wiring area, adjacent to a side with the four second semiconductor devices 200 for the lower arm relative to the main wiring area when viewed from top, on the front surface of the main substrate 2010.

The plurality of control connectors 2050 are mounted on the front surface of the main substrate 2010 and are electrically connected to the plurality of control devices 2020. The control connectors 2050 correspond to the control connectors 1650 in the semiconductor module 1600. In the present variant, the first control connector 2050a is arranged in the first control wiring area on the front surface of the main substrate 2010, and is electrically connected to each first control device 2020a. The second control connector 2050b is arranged in the second control wiring area on the front surface of the main substrate 2010, and is electrically connected to each second control device 2020b.

An inverter device having multiple phases may be implemented by having a number of the semiconductor modules 2000 mounted thereon corresponding to a number of phases. For example, an inverter device for three phases is implemented by providing the semiconductor module 2000 for the U-phase, the semiconductor module 2000 for the V-phase, and the semiconductor module 2000 for the W-phase parallel. The plurality of semiconductor modules 2000 may be arranged side by side in a lateral direction in the figure. Instead of the above, the inverter device having multiple phases may be implemented by mounting a basic block for the multiple phases using one main substrate, in which the semiconductor module 2000 illustrated in this figure is used as the basic block.

FIG. 21 illustrates a semiconductor module 2100 according to a sixth variant of the present embodiment together with the a film capacitor 2180. Because the present variant is a variant of the semiconductor module 1600 illustrated in FIGS. 16 to 17, a description thereof is omitted below except for a difference therebetween. A change similar to the present variant may be added to each of the semiconductor module 800 illustrated in FIGS. 8 to 9, the semiconductor module 1800 illustrated in FIG. 18, the semiconductor module 1900 illustrated in FIG. 19, and the semiconductor module 2000 illustrated in FIG. 20. The semiconductor module 2100 includes one or more semiconductor devices 200, a main substrate 2110, one or more control devices 2120, and one or more control connectors 2150.

Similarly to the semiconductor module 1600, the semiconductor module 2100 according to the present variant is an inverter device. In the example of this figure, the semiconductor module 2100 is a three-phase inverter. For each phase, four semiconductor devices 200 are allocated to an upper arm and four semiconductor devices 200 are allocated to a lower arm. Therefore, the semiconductor module 2100 includes twenty-four, which is calculated by three phases * (four for the upper arm and four for the lower arm), semiconductor devices 200. Similarly to the semiconductor module 1600 illustrated in FIGS. 16 to 17, the semiconductor module 2100 has a structure in which a plurality of semiconductor devices 200 are sandwiched between the main substrate 2110 and a heat radiator, not shown, on a back side in the figure. Thus, the plurality of semiconductor devices 200 are not shown in FIG. 21. Similar to the semiconductor module 1900 as an example, the semiconductor module 2100 may have a configuration in which some semiconductor devices 200 are each replaced with the semiconductor device 1500.

The main substrate 2110 corresponds to the main substrate 1610 of the semiconductor module 1600. On the back surface of the main substrate 2110, the twelve semiconductor devices 200 for the upper arms, which are the first semiconductor devices 200, are arrayed in a line side by side on a right-hand side relative to the twelve first control devices 2120a in the figure, and the twelve semiconductor devices 200 for the lower arms, which are the second semiconductor devices 200, are arrayed in a line side by side on a left-hand side relative to the twelve second control devices 2020b in the figure.

The main substrate 2110 has a P terminal and an N terminal in a vicinity of an edge on an upper side in the figure on the front surface. The main substrate 2110 has each output terminal of a U terminal, a V terminal, and a W terminal in a vicinity of an edge, on a side opposite to the edge where the P terminal and the N terminal are provided, on the front surface. The P wiring between the P terminal and each semiconductor device 200 for the upper arms, the N wiring between the N terminal and each semiconductor device 200 for the lower arms, and the output wiring between each output terminal and each corresponding semiconductor device 200 are provided within the main wiring area corresponding to an extent between the right-hand side relative to the twelve control devices 2120a and the left-hand side relative to the twelve control devices 2120b within the main substrate 2110, and extend in a vertical direction in the figure. The semiconductor module 2100 may have a configuration in which the number of the semiconductor devices for each arm for each phase in the semiconductor module 1800 in FIG. 18 or the semiconductor module 1900 in FIG. 19 is increased from two to four.

The plurality of control devices 2120 are mounted on the front surface of the main substrate 2110. The control devices 2120 correspond to the control devices 1620 of the semiconductor module 1600. In the present variant, each of the twelve control devices 2120a, which is the first control device 2120a, controls each of the twelve first semiconductor devices 200 for the upper arms. The twelve first control devices 2120a are arranged side by side in the vertical direction in the figure in the first control wiring area, adjacent to a side with the twelve first semiconductor devices 200 for the upper arms relative to the main wiring area when viewed from top, on the front surface of the main substrate 2110. Each of the twelve control devices 2120b, which is the second control device 2120b, controls each of the twelve second semiconductor devices 200 for the lower arms. The twelve second control devices 2120b are arranged side by side in the vertical direction in the figure in the second control wiring area, adjacent to a side with the twelve second semiconductor devices 200 for the lower arms relative to the main wiring area when viewed from top, on the front surface of the main substrate 2010.

The plurality of control connectors 2150 are mounted on the front surface of the main substrate 2110 and are electrically connected to the plurality of control devices 2120. The control connectors 2150 correspond to the control connectors 1650 in the semiconductor module 1600. In the present variant, one first control connector 2150a is provided for each upper arm for each phase. Each first control connector 2150a is arranged in the first control wiring area on the front surface of the main substrate 2110 and is electrically connected to each of the four first control devices 2120a corresponding to each phase. One second control connector 2150b is provided for each lower arm for each phase. Each second control connector 2150b is arranged in the second control wiring area on the front surface of the main substrate 2110 and is electrically connected to each of the four second control devices 2120b corresponding to each phase.

The film capacitor 2180 can be coupled to the semiconductor module 2100 at an edge where the P terminal and the N terminal are provided in the semiconductor module 2100. The film capacitor 2180 may have a width, which is a length in a lateral direction in the figure, substantially the same as that of the semiconductor module 2100 or may have a width that is greater or smaller than the semiconductor module 2100. The film capacitor 2180 is electrically connected to an extent between the P terminal and the N terminal. The film capacitor 2180 is a capacitor having a capacity larger than that of a snubber capacitor such as the snubber capacitor 1640. The film capacitor 2180 stabilizes an electrical potential of the P terminal and the N terminal of the semiconductor module 2100, and reduces fluctuation of the electrical potential of the P terminal and the N terminal even when a magnitude of a current output from each output terminal changes largely. The semiconductor module 2100 may be connected to a capacitor of a kind other than the film capacitor, instead of the film capacitor 2180. The semiconductor module 800 illustrated in FIGS. 8 to 9, the semiconductor module 1600 illustrated in FIGS. 16 to 17, the semiconductor module 1800 illustrated in FIG. 18, the semiconductor module 1900 illustrated in FIG. 19, and the semiconductor module 2000 illustrated in FIG. 20 may connect the capacitor such as the film capacitor 2180 to an extent between the P terminal and the N terminal.

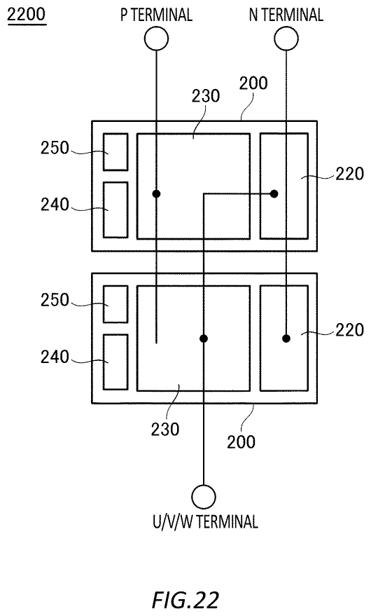

FIG. 22 illustrates the semiconductor module 2200 according to a seventh variant of the present embodiment. Because the present variant is a variant of the semiconductor module 800 illustrated in FIG. 10, the semiconductor module 1800 illustrated in FIG. 18, and the semiconductor module 1900 illustrated in FIG. 19, a description thereof is omitted below except for a difference therebetween. A change similar to the present variant may be added to each of the semiconductor module 2000 illustrated in FIG. 20 and the semiconductor module 2100 illustrated in FIG. 21. The semiconductor module 2200 includes a plurality of semiconductor devices 200.

In the present variant, on the back surface of the main substrate such as the main substrate 810, the main substrate 1610, the main substrate 2010, or the main substrate 2110, each of the at least one first semiconductor device 200 and a corresponding second semiconductor device 200 among the at least one second semiconductor device 200 are arranged side by side in a direction orthogonal to the line formed by the first main electrode plate 220, the second main electrode plate 230, and the control electrode plate 240, which is the array direction of the electrode plates in the semiconductor device 200. In the example of this figure, the first semiconductor device 200 on an upper side in the figure and the second semiconductor device 200 on a lower side in the figure are arranged side by side in a direction orthogonal to the array direction of each electrode plate.

A positive terminal of the semiconductor module 2200 is connected via positive wiring to the main electrode plate on a positive side, which is the second main electrode plate 230 of the semiconductor device 200 on the upper side in the example of this figure, among the first main electrode plate 220 and the second main electrode plate 230 of the first semiconductor device 200. A negative terminal of the semiconductor module 2200 is connected via negative wiring to the main electrode plate on a negative side, which is the first main electrode plate 220 of the semiconductor device 200 on the lower side in the example of this figure, among the first main electrode plate 220 and the second main electrode plate 230 of the second semiconductor device 200. An output terminal of the semiconductor module 2200 is connected via output wiring to the main electrode plate on the negative side, which is the first main electrode plate 220 of the semiconductor device 200 on the upper side in the example of this figure, among the first main electrode plate 220 and the second main electrode plate 230 of the first semiconductor device 200 and the main electrode plate on the positive side, which is the second main electrode plate 230 of the semiconductor device 200 on the lower side in the example of this figure, among the first main electrode plate 220 and the second main electrode plate 230 of the second semiconductor device 200.

In the semiconductor module 2200, the positive wiring, the negative wiring, and the output wiring extend in a direction in which each of the at least one first semiconductor device 200 and a corresponding second semiconductor device 200 among the at least one second semiconductor device 200 are arranged side by side with each other. In the example of this figure, the positive wiring, the negative wiring, and the output wiring extend in a vertical direction in the figure.

In the example of this figure, the semiconductor module 2200 includes one semiconductor device 200 for each arm. Instead of the above, the semiconductor module 2200 may include two or more semiconductor devices 200 for each arm, and two or more first semiconductor devices 200 and two or more second semiconductor devices 200 may be arranged side by side in a line in a direction orthogonal to the array direction of the electrode plates. The semiconductor module 2200 may include one or two or more first semiconductor devices 200 and one or two or more second semiconductor devices 200 for each of multiple phases, and these semiconductor devices 200 may be arranged side by side in a line in a direction orthogonal to the array direction of the electrode plates.

FIG. 23 is a schematic view of a cross-section of a semiconductor module 2300 according to an eighth variant of the present embodiment. Because the present variant is a variant of the semiconductor module 1600 illustrated in FIG. 16 regarding its overall structure and is a variant of the semiconductor module 800 illustrated in FIGS. 8 to 14 regarding its cross-sectional structure, a description thereof is omitted below except for a difference therebetween. A change similar to the present variant may be added to each of the semiconductor module 1800 illustrated in FIG. 18, the semiconductor module 1900 illustrated in FIG. 19, the semiconductor module 2000 illustrated in FIG. 20, the semiconductor module 2100 illustrated in FIG. 21, and the semiconductor module 2200 illustrated in FIG. 22.

The semiconductor module 2300 may be manufactured by a manufacturing method illustrated in FIG. 11. In S1100, one or more semiconductor devices 200 are prepared, each of which has a switching element in which the first main electrode plate 220, the second main electrode plate 230, and the control electrode plate 240 are provided on one surface, the first main electrode is connected to the first main electrode plate 220, and the second main electrode is connected to the second main electrode plate 230, and the control electrode is connected to the control electrode plate 240. Some of the semiconductor devices may be a semiconductor device 1500 instead of the semiconductor device 200.

In S1110, the main substrate 1610 is prepared, to a back surface of which the first main electrode plate 220, the second main electrode plate 230, the sub-electrode plate 250, and the control electrode plate 240 of the at least one semiconductor device 200 are connected. In the present variant, the main substrate 1610 has, on the back surface, at least one main substrate concave portion 2315 into which at least a part of the at least one semiconductor device 200 is embedded. The main substrate 1610 may have a discrete main substrate concave portion 2315 for each of all the semiconductor devices 200 mounted on the back surface of the main substrate 1610. Instead of the above, the main substrate 1610 may have a common main substrate concave portion 2315 for two or more semiconductor devices 200.

The main substrate concave portion 2315 may have a depth equal to or larger than a thickness of the semiconductor device 200 to receive an entirety of the semiconductor device 200 within the concave portion. Instead of the above, the main substrate concave portion 2315 may have a depth smaller than the thickness of the semiconductor device 200, so that only a portion of the semiconductor device 200 is received within the concave portion and a remaining portion protrudes from the back surface of the main substrate 1610.

In S1120, at least one control device 1620 is mounted on a front surface of the main substrate 1610 by, for example, soldering the at least one control device 1620 to the front surface of the main substrate 1610. In the present variant, the control device 1620 is arranged in the control wiring area located on a side with the connected semiconductor device 200 relative to the main wiring area in which main wiring connected to the first main electrode plate 220 and the second main electrode plate 230 of the semiconductor device 200 is arranged.

In S1130, the at least one semiconductor device 200 is sandwiched between the back surface of the main substrate 1610 and the heat radiator 1630, and each electrode plate of the semiconductor device 200 is connected to the back surface of the main substrate 1610. The first main electrode plate 220, the second main electrode plate 230, and the control electrode plate 240 of the at least one semiconductor device 200 are connected to the main substrate 1610 at a bottom surface of the at least one main substrate concave portion 2315. In S1120 and S1130, after the at least one semiconductor device 200 is connected on the back surface of the main substrate 1610, the at least one control device 1620 may be mounted on the front surface of the main substrate 1610.

The heat radiator 1630 is attached to the back surface to which the at least one semiconductor device 200 is connected in the main substrate 1610. Thus, the heat radiator 830 is attached to a surface, on a side opposite to the main substrate 1610, of each semiconductor device 200.

A thermal conductive material 2390 may be provided by being, for example, embedded, applied, injected, or stuck to a part or entirety of a gap between the main substrate 1610 and the heat radiator 1630. The thermal conductive material 2390 may be paste thermal conductive grease or filler, a heat conduction sheet or heat dissipation sheet, or any other Thermal Interface Material or TIM. The thermal conductive material 2390 can increase heat conductivity between a surface, on a side with the insulating substrate 500 or the heat conductor plate 1270, of the semiconductor device 200 and the back surface of the main substrate 1610 and the heat radiator 1630, so that the semiconductor device 200 and the main substrate 1610 can be efficiently cooled.

The main substrate 1610 is fastened to the heat radiator 1630 by at least one thermally conductive fastening member 1660 penetrating a plate-shaped member of the heat radiator 1630 from the front surface of the main substrate 1610 to the at least one protruding member 1670. As an example, each fastening member 1660 may be a screw and each protruding member 1670 may have a screw hole into which this screw is fitted. The fastening member 1660 and the protruding member 1670 may each be made of metal, for example, copper, aluminum, iron, or stainless steel. Thus, the fastening member 1660 for fastening the heat radiator 1630 to the main substrate 1610 propagates heat from the main substrate 1610 to the protruding member 1670 and the protruding member 1670 can release the heat from the fastening member 1660 to a coolant. Therefore, the fastening member 1660 and the protruding member 1670 can increase the cooling performance of the main substrate 1610.

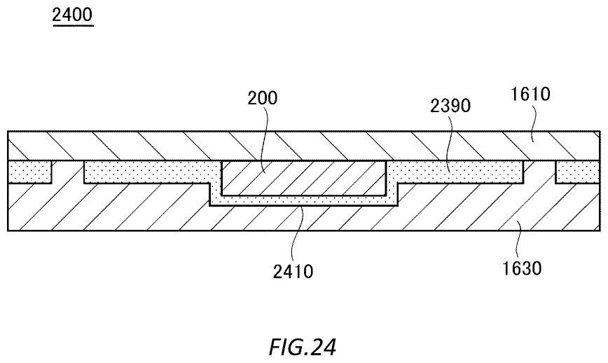

FIG. 24 is a schematic view of a cross-section of a semiconductor module 2400 according to a ninth variant of the present embodiment. Because the present variant is a variant of the semiconductor module 2300 illustrated in FIG. 23, a description thereof is omitted below except for a difference therebetween. A change similar to the present variant may be added to each of the semiconductor module 800 illustrated in FIGS. 8 to 14, the semiconductor module 1600 illustrated in FIG. 16, the semiconductor module 1800 illustrated in FIG. 18, the semiconductor module 1900 illustrated in FIG. 19, the semiconductor module 2000 illustrated in FIG. 20, the semiconductor module 2100 illustrated in FIG. 21, and the semiconductor module 2200 illustrated in FIG. 22.

In the present variant, the main substrate 1610 does not have the main substrate concave portion 2315, and the heat radiator 1630 has, in a surface on a side with at least one semiconductor device 200, at least one heat radiator concave portion 2410 into which at least a part of the at least one semiconductor device 200 is embedded. The heat radiator 1630 may have a discrete heat radiator concave portion 2410 for each of all the semiconductor devices 200 mounted on the back surface of the main substrate 1610. Instead of the above, the heat radiator 1630 may have a common heat radiator concave portion 2410 for two or more semiconductor devices 200. The heat radiator concave portion 2410 may have a depth smaller than the thickness of the semiconductor device 200, so that only a part of the semiconductor device 200 is received within the concave portion and a remaining portion protrudes from an upper surface in the figure of the heat radiator 1630. Instead of the above, the heat radiator concave portion 2410 may have a depth almost equal to the thickness of the semiconductor device 200, so that the entirety of the semiconductor device 200 is received within the concave portion.

The thermal conductive material 2390 may be in a paste or liquid form, and may also be filled within the heat radiator concave portion 2410. On the bottom surface of the heat radiator concave portion 2410, one or more grooves may be formed from below to around the semiconductor device 200. The one or more grooves may be formed to surround a side surface of the heat radiator concave portion 2410. Thus, when the heat radiator 1630 is pressed against the main substrate 1610 for fastening the heat radiator 1630 to the main substrate 1610, an excess amount of the thermal conductive material 2390 flows from below to around the semiconductor device 200 through the plurality of grooves. Thus, the semiconductor module 2400 can bring the heat radiator 1630 to be in closer contact with the semiconductor device 200.

The semiconductor module 2400 has the heat radiator concave portion 2410 on a side with the heat radiator 1630 to narrow the gap between the main substrate 1610 and the heat radiator 1630, so that the cooling efficiency of the main substrate 1610 can be increased. The main substrate 1610 of the semiconductor module 2400 may further have the main substrate concave portion 2315 to receive the semiconductor device 200 between the main substrate concave portion 2315 and the heat radiator concave portion 2410.

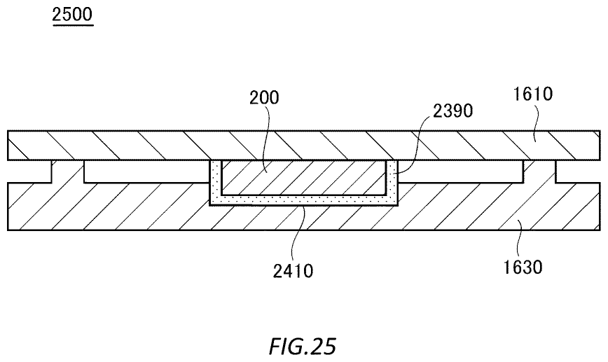

FIG. 25 is a schematic view of a cross-section of a semiconductor module 2500 according to a tenth variant of the present embodiment. Because the present variant is a variant of the semiconductor module 2400 illustrated in FIG. 24, a description thereof is omitted below except for a difference therebetween. A change similar to the present variant may be added to each of the semiconductor module 800 illustrated in FIGS. 8 to 14, the semiconductor module 1600 illustrated in FIG. 16, the semiconductor module 1800 illustrated in FIG. 18, the semiconductor module 1900 illustrated in FIG. 19, the semiconductor module 2000 illustrated in FIG. 20, the semiconductor module 2100 illustrated in FIG. 21, and the semiconductor module 2200 illustrated in FIG. 22.

In the present variant, the thermal conductive material 2390 is provided only in a vicinity or a periphery of each semiconductor device 200 in the gap between the main substrate 1610 and the heat radiator 1630. In the example of this figure, the thermal conductive material 2390 is filled within the heat radiator concave portion 2410 to cover a surface on the side with the heat radiator 1630 and a side surface of the semiconductor device 200. Thus, the semiconductor module 2500 can increase the cooling efficiency of the semiconductor device 200.

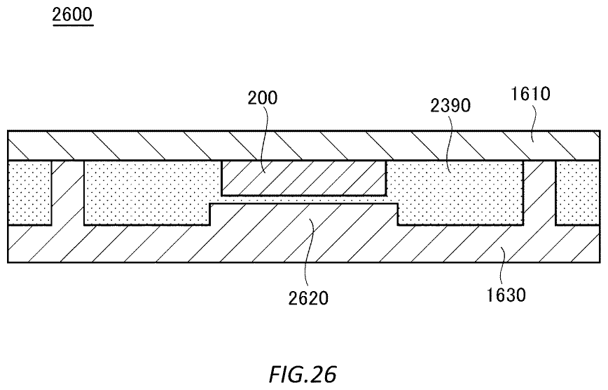

FIG. 26 is a schematic view of a cross-section of a semiconductor module 2600 according to an eleventh variant of the present embodiment. Because the present variant is a variant of the semiconductor module 2300 illustrated in FIG. 23, a description thereof is omitted below except for a difference therebetween. A change similar to the present variant may be added to each of the semiconductor module 800 illustrated in FIGS. 8 to 14, the semiconductor module 1600 illustrated in FIG. 16, the semiconductor module 1800 illustrated in FIG. 18, the semiconductor module 1900 illustrated in FIG. 19, the semiconductor module 2000 illustrated in FIG. 20, the semiconductor module 2100 illustrated in FIG. 21, and the semiconductor module 2200 illustrated in FIG. 22.

In the present variant, the main substrate 1610 does not have the main substrate concave portion 2315, and the heat radiator 1630 has, in a surface on a side with at least one semiconductor device 200, at least one heat radiator convex portion 2620 at a position corresponding to the at least one semiconductor device 200. The heat radiator 1630 may have the heat radiator convex portion 2620 for each of all the semiconductor devices 200 mounted on the back surface of the main substrate 1610. Instead of the above, the heat radiator 1630 may have a common heat radiator convex portion 2620 for two or more semiconductor devices 200.

On an upper surface of the heat radiator convex portion 2620, one or more grooves may be formed from below to around the semiconductor device 200. Thus, when the heat radiator 1630 is pressed against the main substrate 1610 for fastening the heat radiator 1630 to the main substrate 1610, an excess amount of the thermal conductive material 2390 flows from below to around the semiconductor device 200 through the plurality of grooves. Thus, the semiconductor module 2600 can bring the heat radiator 1630 to be in closer contact with the semiconductor device 200.

The semiconductor module 2600 has the heat radiator convex portion 2620 on a side with the heat radiator 1630 to narrow the gap between the semiconductor device 200 and the heat radiator 1630, so that the cooling efficiency of the semiconductor device 200 can be increased. The main substrate 1610 of the semiconductor module 2600 may further have the main substrate concave portion 2315 to receive at least a part of the semiconductor device 200. The main substrate 1610 may have the main substrate convex portion at a position to which each semiconductor device 200 is connected.

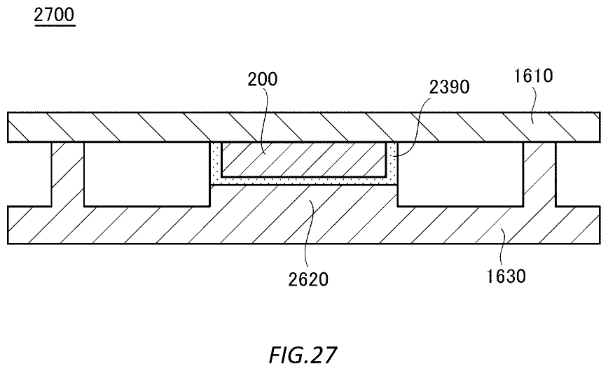

FIG. 27 is a schematic view of a cross-section of a semiconductor module 2700 according to a twelfth variant of the present embodiment. Because the present variant is a variant of the semiconductor module 2600 illustrated in FIG. 26, a description thereof is omitted below except for a difference therebetween. A change similar to the present variant may be added to each of the semiconductor module 800 illustrated in FIGS. 8 to 14, the semiconductor module 1600 illustrated in FIG. 16, the semiconductor module 1800 illustrated in FIG. 18, the semiconductor module 1900 illustrated in FIG. 19, the semiconductor module 2000 illustrated in FIG. 20, the semiconductor module 2100 illustrated in FIG. 21, and the semiconductor module 2200 illustrated in FIG. 22.

In the present variant, the thermal conductive material 2390 is provided only in a vicinity or a periphery of each semiconductor device 200 in the gap between the main substrate 1610 and the heat radiator 1630. In the example of this figure, the thermal conductive material 2390 is arranged by being, for example, applied on the heat radiator convex portion 2620, and covers a surface on a side with the heat radiator 1630 and a side surface of the semiconductor device 200. Thus, the semiconductor module 2700 can increase cooling efficiency of the semiconductor device 200.

While the present invention has been described with the embodiments, the technical scope of the present invention is not limited to the above-described embodiments. It is apparent to persons skilled in the art that various alterations or improvements can be added to the above-described embodiments. It is also apparent from the scope of the claims that the embodiments added with such alterations or improvements can be included in the technical scope of the present invention.

The operations, procedures, steps, stages, or the like of each process performed by a device, system, program, and method shown in the claims, embodiments, or diagrams can be realized in any order as long as the order is not indicated by “prior to,” “before,” or the like and as long as the output from a previous process is not used in a later process. Even if the process flow is described using phrases such as “first” or “next” in the claims for convenience, embodiments, or diagrams, it does not necessarily mean that the process must be performed in this order.

According to this specification, each aspect illustrated below is also disclosed.

A first aspect provides a semiconductor device including: a switching element having a first main electrode and a control electrode on one surface and having a second main electrode on an opposite surface; and a mounting substrate having first main electrode wiring connected to the first main electrode and control wiring connected to the control electrode on a mounting surface for the switching element and having a first main electrode plate connected to the first main electrode wiring and a control electrode plate connected to the control electrode in an area, where the switching element is not arranged, on the mounting surface for the switching element.

The semiconductor device described above may include an encapsulating portion which covers a mounting surface for the switching element in the mounting substrate and a surface of the switching element on a side with the mounting substrate while exposing the first main electrode plate, the second main electrode or a second main electrode plate connected to the second main electrode, and the control electrode plate.

The switching element may be arranged between the first main electrode plate and the control electrode plate on the mounting surface for the switching element in the mounting substrate in any of the semiconductor devices described above.

In any of the semiconductor devices described above, the first main electrode wiring may have a plurality of bumps in contact with the first main electrode and the control wiring may have a plurality of bumps in contact with the control electrode.

In any of the semiconductor devices described above, the mounting substrate may have an insulating substrate, the first main electrode wiring, the first main electrode plate, the control wiring and the control electrode plate that are formed on the insulating substrate.

In any of the semiconductor devices described above, the mounting substrate may have a heat conductor plate formed on a surface, on a side opposite to the mounting surface, of the insulating substrate.

In any of the semiconductor devices described above, the mounting substrate may further have sub-wiring connected to the first main electrode on the mounting surface for the switching element, and may have a sub-electrode plate connected to the sub-wiring in an area in the mounting surface for the switching element where the switching element is not arranged.

In any of the semiconductor devices described above, the switching element may be a power MOSFET, IGBT, or HEMT.

In any of the semiconductor devices described above, the switching element may be a Si semiconductor, SiC semiconductor element or GaN semiconductor element.

A second aspect provides a semiconductor module including: at least one semiconductor device; a main substrate, to a back surface of which the first main electrode plate, the second main electrode or a second main electrode plate connected to the second main electrode, and the control electrode plate of the at least one semiconductor device are connected; and a heat radiator in contact with a surface, on a side opposite to the main substrate, of the at least one semiconductor device.

In the semiconductor module described above, the main substrate may have, on a front surface, a terminal connected to the first main electrode plate of the at least one semiconductor device via wiring within the main substrate and a terminal connected to the second main electrode or the second main electrode plate via wiring within the main substrate.

In any of the semiconductor modules described above, at least one control device, which is mounted on the front surface of the main substrate, for controlling at least one semiconductor device may be included.

Any of the semiconductor modules described above is an inverter device, and the at least one semiconductor device may include a plurality of semiconductor devices respectively allocated to an upper arm and a lower arm for each phase among one or more phases.

In any of the semiconductor modules described above, each semiconductor device allocated to the upper arm for each phase among the plurality of semiconductor devices is arranged in a line on the back surface of the main substrate, and each semiconductor device allocated to the lower arm for each phase among the plurality of semiconductor devices may be arranged in a line side by side with the line of each semiconductor device allocated to the upper arm for each phase on the back surface of the main substrate.

On the back surface of the main substrate in any of the semiconductor modules described above, each semiconductor device allocated to the upper arm for each phase is arranged in an orientation in which the first main electrode plate is positioned on a side with the semiconductor device allocated to an opposing lower arm among the plurality of semiconductor devices, and, on the back surface of the main substrate, each semiconductor device allocated to the lower arm for each phase may be arranged in an orientation in which the first main electrode plate is positioned on a side with the semiconductor device allocated to an opposing upper arm among the plurality of semiconductor device.

A third aspect provides a manufacturing method including: preparing a switching element having a first main electrode and a control electrode on one surface and having a second main electrode on an opposite surface; making a mounting substrate having first main electrode wiring and control wiring on a mounting surface on which the switching element is intended to be mounted; mounting the switching element on the mounting surface, on which the switching element is intended to be mounted, of the mounting substrate by bonding the first main electrode to the first main electrode wiring and bonding the control electrode to the control wiring; and bonding a first main electrode plate connected to the first main electrode wiring and a control electrode plate connected to the control electrode in an area where the switching element is not arranged on the mounting surface on which the switching element of the mounting substrate is intended to be mounted.

The manufacturing method described above may further include encapsulating using an encapsulating material covering the mounting surface for the switching element of the mounting substrate and a surface, on a side with the mounting substrate, of the switching element while exposing the first main electrode plate, the second main electrode or a second main electrode plate connected to the second main electrode, and the control electrode plate.

Any of the manufacturing methods described above may further include: preparing a main substrate to a back surface of which the first main electrode plate, the second main electrode or a second main electrode plate connected to the second main electrode, and the control electrode plate of the at least one semiconductor device are connected; connecting the at least one semiconductor device to the back surface of the main substrate; and attaching a heat radiator to a surface, on a side opposite to the main substrate, of the at least one semiconductor device.

Any of the manufacturing methods described above may include mounting at least one control device which controls the at least one semiconductor device onto the front surface of the main substrate.

### EXPLANATION OF REFERENCES

10: switching element, 100: first main electrode, 110: control electrode, 120: second main electrode, 130: sense electrode, 200: semiconductor device, 210: mounting substrate, 220: first main electrode plate, 230: second main electrode plate, 240: control electrode plate, 250: sub-electrode plate, 260: encapsulating portion, 500: insulating substrate, 510: first main electrode wiring, 513: first main electrode contact, 515: wiring, 517: first main electrode plate contact, 520: control wiring, 523: control electrode contact, 525: wiring, 527: control electrode plate contact, 530: sub-wiring, 535: wiring, 537: sub-electrode plate contact, 800: semiconductor module, 810: main substrate, 812: P wiring, 813: N wiring, 814: U wiring, 815: V wiring, 816: W wiring, 820: control device, 830: heat radiator, 1270: heat conductor plate, 1280: first main electrode plate contact, 1285: second main electrode plate contact, 1290: control electrode plate contact, 1500: semiconductor device, 1510: mounting substrate, 1520: first main electrode plate, 1530: second main electrode plate, 1540: control electrode plate, 1550: sub-electrode plate, 1560: encapsulating portion, 1600: semiconductor module, 1610: main substrate, 1620: control device, 1630: heat radiator, 1640: snubber capacitor, 1650: control connector, 1660: fastening member, 1670: protruding member, 1710: protruding member, 1800: semiconductor module, 1812: P wiring, 1813: N wiring, 1814: U wiring, 1815: V wiring, 1816: W wiring, 1900: semiconductor module, 1912: P wiring, 1913: N wiring, 1914: U wiring, 1915: V wiring, 1916: W wiring, 2000: semiconductor module, 2010: main substrate, 2020: control device, 2050: control connector, 2100: semiconductor module, 2110: main substrate, 2120: control device, 2150: control connector, 2180: film capacitor, 2200: semiconductor module, 2300: semiconductor module, 2315: main substrate concave portion, 2390: thermal conductive material, 2400: semiconductor module, 2410: heat radiator concave portion, 2500: semiconductor module, 2600: semiconductor module, 2620: heat radiator convex portion, 2700: semiconductor module.

What is claimed is:

1. A semiconductor device, comprising:
a switching element having a first main electrode and a control electrode on one surface and having a second main electrode on an opposite surface; and
a mounting substrate having first main electrode wiring connected to the first main electrode and control wiring connected to the control electrode on a mounting surface for the switching element and having a first main electrode plate connected to the first main electrode wiring and a control electrode plate connected to the control electrode in an area, where the switching element is not arranged, on the mounting surface for the switching element.

2. The semiconductor device according to claim 1, further comprising an encapsulating portion covering the mounting surface for the switching element of the mounting substrate and a surface, on a side with the mounting substrate, of the switching element while exposing the first main electrode plate, the second main electrode or a second main electrode plate connected to the second main electrode, and the control electrode plate.

3. The semiconductor device according to claim 1, wherein the switching element is arranged between the first main electrode plate and the control electrode plate on the mounting surface for the switching element in the mounting substrate.

4. The semiconductor device according to claim 1, wherein
the first main electrode wiring has a plurality of bumps in contact with the first main electrode, and
the control wiring has a plurality of bumps in contact with the control electrode.

5. The semiconductor device according to claim 1, wherein
the mounting substrate has:
an insulating substrate; and
the first main electrode wiring, the first main electrode plate, the control wiring and the control electrode plate that are formed on the insulating substrate.

6. The semiconductor device according to claim 5, wherein
the mounting substrate has a heat conductor plate formed on a surface, on a side opposite to the mounting surface, of the insulating substrate.

7. The semiconductor device according to claim 1, wherein
the mounting substrate further has sub-wiring connected to the first main electrode on the mounting surface for the switching element and has a sub-electrode plate connected to the sub-wiring in an area, where the switching element is not arranged, on the mounting surface for the switching element.

8. The semiconductor device according to claim 1, wherein the switching element is a power MOSFET or IGBT.

9. The semiconductor device according to claim 1, wherein the switching element is a SiC semiconductor element.

10. A semiconductor module, comprising:
at least one semiconductor device, each of which is the semiconductor device according to claim 1;
a main substrate, to a back surface of which the first main electrode plate, the second main electrode or a second main electrode plate connected to the second main electrode, and the control electrode plate of the at least one semiconductor device are connected; and
a heat radiator in contact with a surface, on a side opposite to the main substrate, of the at least one semiconductor device.

11. The semiconductor module according to claim 10, wherein the main substrate has, on its front surface, a terminal connected to the first main electrode plate of the at least one semiconductor device via wiring within the main substrate and a terminal connected to the second main electrode or the second main electrode plate via wiring within the main substrate.

12. The semiconductor module according to claim 10, further comprising at least one control device which controls the at least one semiconductor device mounted on a front surface of the main substrate.

13. The semiconductor module according to claim 10, wherein
the semiconductor module is an inverter device, and
the at least one semiconductor device includes a plurality of semiconductor devices respectively allocated to an upper arm and a lower arm for each phase among one or more phases.

14. The semiconductor module according to claim 13, wherein
each semiconductor device allocated to the upper arm for each phase among the plurality of semiconductor devices is arranged in a line on a back surface of the main substrate, and
each semiconductor device allocated to the lower arm for each phase among the plurality of semiconductor devices is arranged in a line side by side with the line of each semiconductor device allocated to the upper arm for each phase on the back surface of the main substrate.

15. The semiconductor module according to claim 14, wherein
on the back surface of the main substrate, each semiconductor device allocated to the upper arm for each phase is arranged in an orientation in which the first main electrode plate is positioned on a side with the semiconductor device allocated to an opposing lower arm among the plurality of semiconductor devices, and
on the back surface of the main substrate, each semiconductor device allocated to the lower arm for each phase is arranged in an orientation in which the first main electrode plate is positioned on a side with the semiconductor device allocated to an opposing upper arm among the plurality of semiconductor devices.

16. A manufacturing method, comprising:
preparing a switching element having a first main electrode and a control electrode on one surface and having a second main electrode on an opposite surface;
making a mounting substrate having first main electrode wiring and control wiring on a mounting surface on which the switching element is intended to be mounted;
mounting the switching element on the mounting surface, on which the switching element is intended to be mounted, of the mounting substrate by bonding the first main electrode to the first main electrode wiring and bonding the control electrode to the control wiring; and
bonding a first main electrode plate connected to the first main electrode wiring and a control electrode plate connected to the control electrode in an area, where the switching element is not arranged, of the mounting surface on which the switching element of the mounting substrate is intended to be mounted.

17. The manufacturing method according to claim 16, further comprising encapsulating using an encapsulating material covering the mounting surface for the switching element of the mounting substrate and a surface, on a side with the mounting substrate, of the switching element while exposing the first main electrode plate, the second main electrode or a second main electrode plate connected to the second main electrode, and the control electrode plate.

18. The manufacturing method according to claim 16 further comprising:
preparing a main substrate to a back surface of which the first main electrode plate, the second main electrode or a second main electrode plate connected to the second main electrode, and the control electrode plate of at least one semiconductor device are connected;
connecting the at least one semiconductor device to the back surface of the main substrate; and
attaching a heat radiator to a surface, on a side opposite to the main substrate, of the at least one semiconductor device.

19. The manufacturing method according to claim 18, further comprising mounting at least one control device which controls the at least one semiconductor device onto a front surface of the main substrate.

20. A semiconductor module, comprising:
at least one semiconductor device having a switching element in which a first main electrode plate, a second main electrode plate and a control electrode plate are provided on one surface, a first main electrode is connected to the first main electrode plate, a second main electrode is connected to the second main electrode plate, and a control electrode is connected to the control electrode plate;
a main substrate, to a back surface of which the first main electrode plate, the second main electrode plate and the control electrode plate of the at least one semiconductor device are connected; and
a heat radiator provided on a back surface, to which the at least one semiconductor device is connected, of the main substrate.

21. The semiconductor module according to claim 20, wherein
the main substrate has, on the back surface, at least one main substrate concave portion into which at least a part of the at least one semiconductor device is embedded, and
the first main electrode plate, the second main electrode plate and the control electrode plate of the at least one semiconductor device are connected to the main substrate at a bottom surface of the at least one main substrate concave portion.

22. The semiconductor module according to claim 20, comprising a thermal conductive material in at least a part of a gap between the main substrate and the heat radiator.

23. The semiconductor module according to claim 20, wherein the heat radiator has at least one heat radiator convex portion at a position corresponding to the at least one semiconductor device on a surface on a side with the at least one semiconductor device.

24. The semiconductor module according to claim 20, wherein the heat radiator has, on its surface on a side with the at least one semiconductor device, at least one heat radiator concave portion into which at least a part of the at least one semiconductor device is embedded.

25. The semiconductor module according to claim 20, wherein
the heat radiator has:
a plate-shaped member having a surface on a side with the main substrate and the at least one semiconductor device; and
at least one protruding member provided on a surface, opposite to the side with the main substrate and the at least one semiconductor device, of the plate-shaped member, and
the main substrate is fastened to the heat radiator by at least one thermally conductive fastening member which penetrates the plate-shaped member of the heat radiator from a front surface of the main substrate to the at least one protruding member.

26. The semiconductor module according to claim 25, wherein
each of the at least one fastening member is a screw, and
each of the at least one protruding member has a screw hole into which the screw is fitted.

27. The semiconductor module according to claim 20, wherein
the at least one semiconductor device includes at least one first semiconductor device and at least one second semiconductor device, and
a main electrode plate on a negative side among the first main electrode plate and the second main electrode plate of each of the at least one first semiconductor device is electrically connected to a main terminal plate on a positive side among the first main electrode plate and the second main electrode plate of a corresponding second semiconductor device among the at least one second semiconductor device.

28. The semiconductor module according to claim 20, wherein the at least one semiconductor device has a structure in which the second main electrode plate is arranged between a first main electrode plate and the control electrode plate on one surface.

29. The semiconductor module according to claim 28, wherein, on the back surface of the main substrate, each of the at least one first semiconductor device and a corresponding second semiconductor device among the at least one second semiconductor device are arranged in an orientation in which the first main electrode plate of the at least one first semiconductor device and the first main electrode plate of the corresponding second semiconductor device oppose each other.

30. The semiconductor module according to claim 28, wherein, on the back surface of the main substrate, each of the at least one first semiconductor device and a corresponding second semiconductor device among the at least one second semiconductor device are arranged in an orientation in which the first main electrode plate and the control electrode plate oppose each other.

31. The semiconductor module according to claim 28, wherein
the main substrate includes:
a positive terminal connected via positive wiring within the main substrate to a main electrode plate on a positive side among the first main electrode plate and the second main electrode plate of the at least one first semiconductor device;
a negative terminal connected via negative wiring within the main substrate to a main electrode plate on a negative side among the first main electrode plate and the second main electrode plate of the at least one second semiconductor device; and
an output terminal connected via output wiring within the main substrate to a main electrode plate on the negative side among the first main electrode plate and the second main electrode plate of the at least one first semiconductor device and a main electrode plate on the positive side among the first main electrode plate and the second main electrode plate of the at least one second semiconductor device, and
the positive wiring, the negative wiring, and the output wiring are provided in a main wiring area of the main substrate corresponding to an extent between the at least one first semiconductor device and the at least one second semiconductor device when viewed from top.

32. The semiconductor module according to claim 31, comprising:
a first at least one first semiconductor device and a second at least one first semiconductor device arrayed in a line on the back surface of the main substrate, each of the first at least one first semiconductor device and the second at least one first semiconductor device being the at least one first semiconductor device;
a first at least one second semiconductor device and a second at least one second semiconductor device arrayed in a line side by side with the first at least one first semiconductor device and the second at least one first semiconductor device on the back surface of the main substrate, each of the first at least one second semiconductor device and the second at least one second semiconductor device being the at least one second semiconductor device;
a first output terminal connected via a first output wiring within the main substrate to a main electrode plate on the negative side among the first main electrode plate and the second main electrode plate of the first at least one first semiconductor device and a main electrode plate on the positive side among the first main electrode plate and the second main electrode plate of the first at least one second semiconductor device, the first output terminal being the output terminal and the first output wiring being the output wiring; and
a second output terminal connected via a second output wiring within the main substrate to a main electrode plate on the negative side among the first main electrode plate and the second main electrode plate of the second at least one first semiconductor device and a main electrode plate on the positive side among the first main electrode plate and the second main electrode plate of the second at least one second semiconductor device, the second output terminal being the output terminal and the second output wiring being the output wiring,
wherein the positive wiring, the negative wiring, the first output wiring, and the second output wiring are provided in the main wiring area of the main substrate corresponding to an extent between the line of the first at least one first semiconductor device and the second at least one first semiconductor device and the line of the first at least one second semiconductor device and the second at least one second semiconductor device when viewed from top.

33. The semiconductor module according to claim 31, comprising:
at least one first control device which is mounted on a front surface of the main substrate and is electrically connected to the control electrode plate of at least one of the at least one first semiconductor device; and
at least one second control device which is mounted on the front surface of the main substrate and is electrically connected to the control electrode plate of at least one of the at least one second semiconductor device,
wherein the at least one first control device is arranged in a first control wiring area on a side with the at least one first semiconductor device relative to the main wiring area when viewed from top, and
wherein the at least one second control device is arranged in a second control wiring area on a side with the at least one second semiconductor device relative to the main wiring area when viewed from top.

34. The semiconductor module according to claim 33, comprising
a first control connector which is arranged in the first control wiring area on the front surface of the main substrate and is electrically connected to the at least one first control device, and
a second control connector which is arranged in the second control wiring area on the front surface of the main substrate and is electrically connected to the at least one second control device.

35. The semiconductor module according to claim 31, comprising at least one snubber capacitor arranged in the main wiring area on a front surface of the main substrate.

36. The semiconductor module according to claim 28, wherein, on the back surface of the main substrate, each of the at least one first semiconductor device and a corresponding second semiconductor device among the at least one second semiconductor device are arranged side by side with each other in a direction orthogonal to a line of the first main electrode plate, the second main electrode plate, and the control electrode plate.

37. The semiconductor module according to claim 36, wherein
the main substrate includes:
a positive terminal connected via positive wiring within the main substrate to a main electrode plate on a positive side among the first main electrode plate and the second main electrode plate of the at least one first semiconductor device;
a negative terminal connected via negative wiring within the main substrate to a main electrode plate on a negative side among the first main electrode plate and the second main electrode plate of the at least one second semiconductor device; and
an output terminal connected via output wiring within the main substrate to a main electrode plate on the negative side among the first main electrode plate and the second main electrode plate of the at least one first semiconductor device and a main electrode plate on the positive side among the first main electrode plate and the second main electrode plate of the at least one second semiconductor device, and
the positive wiring, the negative wiring, and the output wiring extend in a direction so that each of the at least one first semiconductor device and a corresponding second semiconductor device among the at least one second semiconductor device are arranged side by side with each other.

38. A manufacturing method, comprising:
preparing at least one semiconductor device having a switching element in which a first main electrode plate, a second main electrode plate and a control electrode plate are provided on one surface, a first main electrode is connected to the first main electrode plate, a second main electrode is connected to the second main electrode plate, and a control electrode is connected to the control electrode plate;
preparing a main substrate, to a back surface of which the first main electrode plate, the second main electrode plate and the control electrode plate of the at least one semiconductor device are connected;
connecting the at least one semiconductor device to a back surface of the main substrate; and
attaching a heat radiator to the back surface, to which the at least one semiconductor device is connected, of the main substrate.
